(19) United States
(12) Patent Application Publication
(10) Pub. No.: US 2026/0213731 A1
(43) Pub. Date: Jul. 23, 2026

(54) FILTER DEVICE

(71) Applicant: Murata Manufacturing Co., Ltd., Nagaokakyo-shi (JP)

(72) Inventors: Masakazu MIMURA, Nagaokakyo-shi (JP); Toshimaro YONEDA, Nagaokakyo-shi (JP)

(21) Appl. No.: 19/572,023

(22) Filed: Mar. 19, 2026

Related U.S. Application Data
(63) Continuation of application No. PCT/JP2024/034487, filed on Sep. 26, 2024.

(30) Foreign Application Priority Data
Sep. 29, 2023 (JP) 2023-169962

(51) Int. Cl. H03H 9/56; H03H 9/02; H03H 9/13; H03H 9/17; H03H 9/58

(52) U.S. Cl. CPC H03H 9/568; H03H 9/02031; H03H 9/02102; H03H 9/02157; H03H 9/02228; H03H 9/132; H03H 9/173; H03H 9/175; H03H 9/176; H03H 9/564; H03H 9/581

(57) ABSTRACT

A filter device includes an acoustic wave resonator including a piezoelectric layer with first and second main surfaces, an IDT electrode on the first main surface and including electrode fingers, a first dielectric film on the first main surface, and a second dielectric film on the second main surface. The first and second dielectric films overlap an overlapping region. A fractional bandwidth is about 8.5% or higher, the fractional bandwidth being ((FH−FL)/FC)×100[%], where FH is a highest frequency of the passband, FL is a lowest frequency of the passband, and FC is a center frequency of the passband. 0.322<(Td_f/Tp)+(Td_b/Tp)<0.786 and |(Td_f/Tp)−(Td_b/Tp)|<0.196, where Tp is a thickness of the piezoelectric layer at the overlapping region, Td_f is a thickness of the first dielectric film overlapping the overlapping region, and Td_b is a thickness of the second dielectric film overlapping the overlapping region.

### CROSS REFERENCE TO RELATED APPLICATIONS

This application claims the benefit of priority to Japanese Patent Application No. 2023-169962 filed on Sep. 29, 2023 and is a Continuation Application of PCT Application No. PCT/JP2024/034487 filed on Sep. 26, 2024. The entire contents of each application are hereby incorporated herein by reference.

### BACKGROUND OF THE INVENTION

### 1. Field of the Invention

The present invention relates to filter devices each including an acoustic wave resonator.

### 2. Description of the Related Art

Hitherto, a filter device including an acoustic wave resonator is widely used as a filter of a mobile phone, for example. Lately, an acoustic wave resonator utilizing a bulk wave of a thickness shear mode, such as that disclosed in U.S. Patent Application Publication No. 2021/044272, has been proposed. In this acoustic wave resonator, a piezoelectric layer is disposed on a support. On the piezoelectric layer, an IDT (Interdigital Transducer) is disposed. In the IDT, electrode fingers are alternately arranged. By the application of an AC voltage to between these electrode fingers, a bulk wave of the thickness shear mode is excited.

In U.S. Patent Application Publication No. 2021/044272, the piezoelectric layer has front and back surfaces opposing each other, and the IDT is disposed on the front surface of the piezoelectric layer. A frequency setting layer, which is a dielectric layer, is disposed on each of the front and back surfaces. U.S. Patent Application Publication No. 2021/044272 describes that an A2 mode, which occurs at a higher frequency side than the passband, can be reduced by 20% or more if the ratio of the thickness of the frequency setting layer disposed on the back surface to the total thickness of the frequency setting layers is at least 30%. The A2 mode is a second-order mode in the thickness direction.

### SUMMARY OF THE INVENTION

For a filter device having a wide passband used for a communication system, such as 5G, a ladder circuit configuration, for example, may be used. As a series arm resonator and/or a parallel arm resonator in the ladder circuit configuration, an acoustic wave resonator utilizing a bulk wave of the thickness shear mode may be used.

A typical RF (Radio Frequency) filter is required to exhibit high attenuation characteristics in a frequency band near an integral multiple of the passband. In the acoustic wave resonator utilizing a bulk wave of the thickness shear mode, however, not only the second-order mode, but also higher-order modes, such as third-, fourth-, and fifth-order modes, occur. Such higher-order modes occur in frequencies higher than a frequency range in which the second-order mode occurs. If the third-order mode occurs in a parallel arm resonator in the ladder circuit configuration, a response attributable to the third-order mode appears in a frequency range about twice as high as the passband. This may fail to satisfy the attenuation characteristics in this frequency range.

Example embodiments of the present invention provide filter devices that each increase a passband and also suppress second- and third-order modes in an acoustic wave resonator.

A filter device according to an example embodiment of the present invention is a filter device having a passband and including multiple resonators including an acoustic wave resonator. The acoustic wave resonator includes a piezoelectric layer including first and second main surfaces opposing each other, an IDT electrode directly or indirectly provided on the first main surface of the piezoelectric layer and including multiple electrode fingers, a first dielectric film provided on the first main surface of the piezoelectric layer, and a second dielectric film provided on the second main surface of the piezoelectric layer. A direction perpendicular to an extending direction of the multiple electrode fingers is defined as an electrode-finger perpendicular direction, and as viewed in the electrode-finger perpendicular direction, a region where the electrode fingers adjacent to each other overlap each other is defined as an overlapping region. The first and second dielectric films overlap the overlapping region in a plan view. A fractional bandwidth is about 8.5% or higher, the fractional bandwidth being represented by ((FH−FL)/FC)×100[%], where FH is a highest frequency of the passband, FL is a lowest frequency of the passband, and FC is a center frequency of the passband. A relationship of about 0.322<(Td_f/Tp)+(Td_b/Tp)<about 0.786 and |(Td_f/Tp)−(Td_b/Tp)|<about 0.196, where Tp is a thickness of the piezoelectric layer corresponding to the overlapping region, Td_f is a thickness of the first dielectric film that overlaps the overlapping region in a plan view, and Td_b is a thickness of the second dielectric film that overlaps the overlapping region in a plan view.

Filter devices according to example embodiments of the present invention each increase a passband and also suppress second- and third-order modes in an acoustic wave resonator.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a filter device according to a first example embodiment of the present invention.

FIG. 2 is a schematic elevational cross-sectional view of an acoustic wave resonator in the first example embodiment of the present invention.

FIG. 3 is a schematic plan view of the acoustic wave resonator in the first example embodiment of the present invention.

FIG. 4 is a schematic elevational cross-sectional view of a pair of electrode fingers and its surrounding portion in the acoustic wave resonator in the first example embodiment of the present invention.

FIG. 5 is a graph illustrating the impedance frequency characteristics of an acoustic wave resonator in a comparative example.

FIG. 6 is a graph illustrating the impedance frequency characteristics of the acoustic wave resonator in the first example embodiment of the present invention.

FIG. 7 is a schematic diagram illustrating the thickness-direction displacement distribution of the fundamental mode in an inter-electrode-finger central portion of a multilayer section in the first example embodiment of the present invention.

FIG. 8 is a schematic diagram illustrating the thickness-direction displacement distribution of the second-order mode in the inter-electrode-finger central portion of the multilayer section in the first example embodiment of the present invention.

FIG. 9 is a schematic diagram illustrating the thickness-direction displacement distribution of the third-order mode in the inter-electrode-finger central portion of the multilayer section in the first example embodiment of the present invention.

FIG. 10 is a schematic diagram illustrating the thickness-direction stress distribution of the fundamental mode in the inter-electrode-finger central portion of the multilayer section in the first example embodiment of the present invention.

FIG. 11 is a schematic diagram illustrating the thickness-direction stress distribution of the second-order mode in the inter-electrode-finger central portion of the multilayer section in the first example embodiment of the present invention.

FIG. 12 is a schematic diagram illustrating the thickness-direction stress distribution of the third-order mode in the inter-electrode-finger central portion of the multilayer section in the first example embodiment of the present invention.

FIG. 13 is a schematic diagram illustrating the thickness-direction stress distribution of the third-order mode in the inter-electrode-finger central portion of the multilayer section when the third-order mode is suppressed.

FIG. 14 is a schematic diagram illustrating the thickness-direction stress distribution of the third-order mode in an inter-electrode-finger central portion of a multilayer section in a reference example when the third-order mode is suppressed.

FIG. 15 is a graph illustrating the relationship between the ratio Td_f/Tp and the electromechanical coupling coefficient K²_{eff} of the third-order mode when Td_f=Td_b.

FIG. 16 is a graph illustrating the relationship between the ratio Td_f/Tp and the electromechanical coupling coefficient K²_{eff} of the second-order mode when (Td_f/Tp+Td_b/Tp)=about 0.54.

FIG. 17 is a graph illustrating the relationship between the ratio Td_f/Tp and the ratio Fr3/Fr1.

FIG. 18 is a schematic elevational cross-sectional view illustrating a portion of a filter device according to a first modified example of the first example embodiment of the present invention.

FIG. 19 is a schematic elevational cross-sectional view illustrating a portion of a filter device according to a second modified example of the first example embodiment of the present invention.

FIG. 20 is a schematic elevational cross-sectional view illustrating a portion of a filter device according to a third modified example of the first example embodiment of the present invention.

FIG. 21 is a schematic elevational cross-sectional view of a pair of electrode fingers and its surrounding portion in an acoustic wave resonator according to a fourth modified example of the first example embodiment of the present invention.

FIG. 22 is a schematic elevational cross-sectional view of a pair of electrode fingers and its surrounding portion in an acoustic wave resonator according to a second example embodiment of the present invention.

FIG. 23 is a schematic elevational cross-sectional view of a pair of electrode fingers and its surrounding portion in an acoustic wave resonator according to a third example embodiment of the present invention.

FIG. 24 is a schematic plan view of an acoustic wave resonator according to a fourth example embodiment of the present invention.

FIG. 25 is a schematic elevational cross-sectional view of a pair of electrode fingers and its surrounding portion in an acoustic wave resonator according to a fifth example embodiment of the present invention.

FIG. 26 is a graph illustrating the relationship between Tp/p and the fractional bandwidth of the acoustic wave resonator.

FIG. 27 is a graph illustrating the relationship between the fractional bandwidth of the acoustic wave resonator and the magnitude of a normalized spurious signal.

FIG. 28 is a graph illustrating the relationships between Tp/p, the metallization ratio MR, and the fractional bandwidth.

FIG. 29 is a graph illustrating a map of the fractional bandwidth with respect to the Euler angles (0°, θ, ψ) of LiNbO₃ in a case in which Tp/p is made to approach almost 0.

FIG. 30 is a schematic diagram of the coordinate system obtained by transforming the crystal axes of a piezoelectric crystal using the Euler angles.

FIG. 31 is a schematic diagram illustrating the coordinate system of the piezoelectric layer when the angle θ in the Euler angles (0°, θ, 0°) of lithium niobate of the piezoelectric layer is about 0° to about 60°.

FIG. 32 is a schematic diagram illustrating the coordinate system of the piezoelectric layer when the angle θ in the Euler angles (0°, θ, 90°) of lithium niobate of the piezoelectric layer is about −15° or greater and smaller than about 0°.

FIG. 33 is a schematic diagram illustrating the coordinate system of the piezoelectric layer when the angle θ in the Euler angles (0°, θ, 0°) of lithium niobate of the piezoelectric layer is about 180° to about 240°.

FIG. 34 is a schematic diagram illustrating the coordinate system of the piezoelectric layer when the angle θ in the Euler angles (0°, θ, 90°) of lithium niobate of the piezoelectric layer is about 165° to about 180°.

FIG. 35 illustrates a piezoresponse force microscopy image showing an example in which polarization reversal is occurring in the piezoelectric layer.

FIG. 36 is a graph illustrating the admittance frequency characteristics of the acoustic wave resonator when polarization reversal is occurring in the piezoelectric layer and the admittance frequency characteristics when polarization reversal is not occurring in the piezoelectric layer.

FIG. 37 is a graph illustrating an example of the passband characteristics of the filter device.

### DETAILED DESCRIPTION OF THE EXAMPLE EMBODIMENTS

Example embodiments of the present invention will be described below with reference to the drawings.

The example embodiments disclosed in the specification are only examples and the configurations discussed in different example embodiments may partially be replaced by or combined with each other.

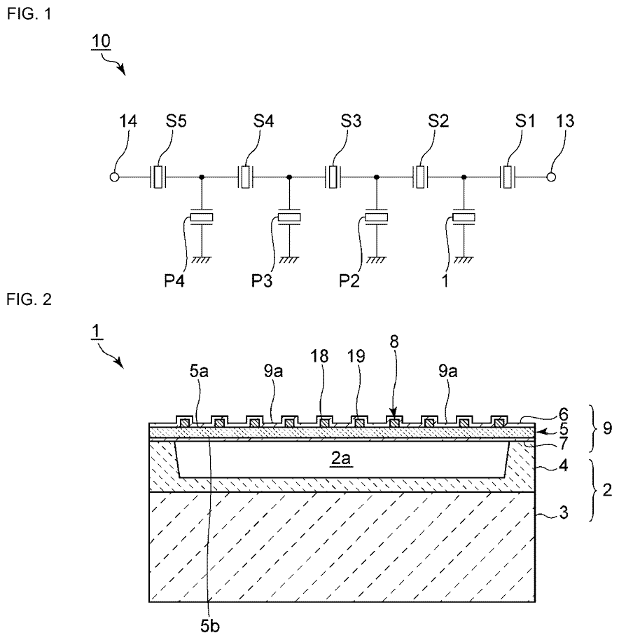

FIG. 1 is a circuit diagram of a filter device according to a first example embodiment of the present invention.

A filter device 10 is a bandpass filter having a passband. In the specification, the passband of a filter device refers to the guaranteed passband specified for this filter device. A specific approach to determining the passband of the filter device will be discussed later. The filter device 10 shown in FIG. 1 is widely used as a communication device, for example. The passband of the filter device 10 is that of n79 band, which is 4400 to 5000 MHz, though it is not limited thereto.

Specifically, the filter device 10 is a ladder filter. As resonators, the filter device 10 includes multiple series arm resonators and multiple parallel arm resonators. The circuit configuration of the filter device 10 is not limited to that shown in FIG. 1. The filter device 10 may be configured differently if it includes a ladder circuit section. The ladder circuit section may be configured differently if it includes at least one series arm resonator and at least one parallel arm resonator.

In the specification, the highest frequency in the passband will be called the upper limit, and the lowest frequency in the passband will be called the lower limit. In the specification, the upper limit and the lower limit of the passband are those of the guaranteed passband specified for the filter device. When the upper limit and the lower limit of the passband are denoted by FH and FL, respectively, and the center frequency of the passband is denoted by FC, the center frequency is expressed by FC=(FH+FL)/2. The fractional bandwidth of the filter device 10 of the first example embodiment, which is represented by ((FH−FL)/FC)×100[%], is about 8.5% or higher, for example. The passband of the filter device 10 is wide in this manner. The upper limit of the fractional bandwidth of the filter device 10 is not particularly limited, but the fractional bandwidth may be about 40% or lower, for example. In this case, the filter device 10 can be manufactured easily.

All the resonators of the filter device 10 are acoustic wave resonators, but the filter device 10 is not limited to this configuration. The resonators of the filter device 10 may include at least one acoustic wave resonator. As illustrated in FIG. 1, the resonators of the filter device 10 include an acoustic wave resonator 1. In the first example embodiment, the acoustic wave resonator 1 is a parallel arm resonator. The specific configuration of the acoustic wave resonator 1 will be described below.

FIG. 2 is a schematic elevational cross-sectional view of the acoustic wave resonator in the first example embodiment.

The acoustic wave resonator 1 includes a piezoelectric layer 5, a first dielectric film 6, a second dielectric film 7, and an IDT electrode 8. The piezoelectric layer 5 includes a first main surface 5a and a second main surface 5b opposing each other. The first dielectric film 6 is disposed on the first main surface 5a. More specifically, the IDT electrode 8 is disposed on the first main surface 5a, and the first dielectric film 6 is disposed on the first main surface 5a to cover the IDT electrode 8. The second dielectric film 7 is disposed on the second main surface 5b.

In the first example embodiment, the piezoelectric layer 5 is made of lithium niobate. More specifically, the piezoelectric layer 5 is made of LiNbO₃. The first and second dielectric films 6 and 7 are made of silicon oxide. More specifically, the first and second dielectric films 6 and 7 are made of SiO₂. In the specification, “a certain member is made of a certain material” includes the meaning that a small amount of impurity is contained in the material to such a degree not to significantly degrade the electrical characteristics of the acoustic wave resonator. The materials for the piezoelectric layer 5 and the first and second dielectric films 6 and 7 are not limited to the above-described materials.

The acoustic wave resonator 1 includes a support 2. The support 2 includes a support substrate 3 and an insulating layer 4. The insulating layer 4 is disposed on the support substrate 3. The second dielectric film 7 is disposed on the insulating layer 4. Accordingly, the piezoelectric layer 5 is indirectly disposed on the insulating layer 4 with the second dielectric film 7 interposed therebetween.

As the material for the support substrate 3, a semiconductor material, such as silicon, or a ceramic material, such as aluminum oxide, may be used. As the material for the insulating layer 4, a suitable dielectric substance, such as silicon oxide or tantalum oxide, may be used. The support 2 may be constituted only by the support substrate 3. Alternatively, the provision of the support 2 may be omitted.

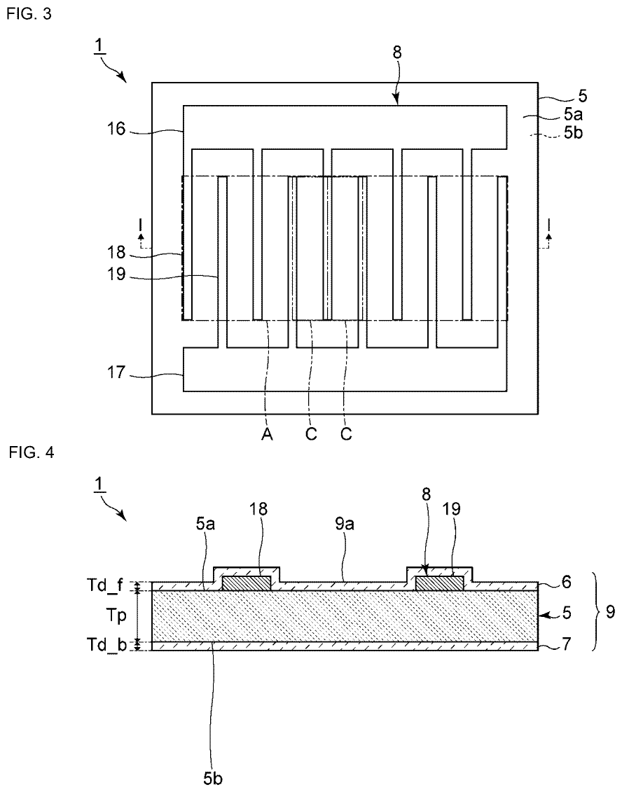

FIG. 3 is a schematic plan view of the acoustic wave resonator in the first example embodiment. The schematic sectional view of FIG. 2 is taken along line I-I in FIG. 3. In FIG. 3, the first dielectric film 6 and lines connected to the acoustic wave resonator 1 are not shown. The same applies to the schematic plan views other than FIG. 3.

The IDT electrode 8 includes a pair of busbars and multiple electrode fingers. The pair of busbars are specifically a first busbar 16 and a second busbar 17 opposing each other. The multiple electrode fingers are specifically first electrode fingers 18 and second electrode fingers 19. One end of each of the first electrode fingers 18 is connected to the first busbar 16. One end of each of the second electrode fingers 19 is connected to the second busbar 17. The first electrode fingers 18 and the second electrode fingers 19 interdigitate each other.

The IDT electrode 8 includes a multilayer metal film. Specifically, the IDT electrode 8 includes a Ti layer and an Al layer in this order as seen from the piezoelectric layer 5. The material for the IDT electrode 8 is not limited to those described above. The IDT electrode 8 may include a single-layer metal film.

Hereinafter, the first and second electrode fingers 18 and 19 may be simply called electrode fingers. The extending direction of the electrode fingers will be called the electrode-finger extending direction. The direction perpendicular to the electrode-finger extending direction will be called the electrode-finger perpendicular direction. As viewed in the electrode-finger perpendicular direction, the region where the adjacent first and second electrode fingers 18 and 19 overlap each other is defined as an overlapping region A. The first and second dielectric films 6 and 7 are located to overlap the overlapping region A in a plan view.

In the specification, “in a plan view” refers to viewing along the stacking direction of the support 2 and the piezoelectric layer 5 from the direction viewed from above in FIG. 2. In FIG. 2, for example, the piezoelectric layer 5 is located at a higher position than the support substrate 3. In the specification, “in a plan view” is synonymous with viewing in a main-surface opposing direction. The main-surface opposing direction is the direction in which the first main surface 5a and the second main surface 5b of the piezoelectric layer 5 oppose each other. More specifically, the main-surface opposing direction is a direction normal to the first main surface 5a, for example.

The acoustic wave resonator 1 is an acoustic wave resonator configured to utilize a bulk wave of the thickness shear mode. Specifically, the acoustic wave resonator 1 in the first example embodiment is configured to utilize a bulk wave of the fundamental thickness shear mode as the principal mode. More specifically, in the acoustic wave resonator 1, Tp/p is about 0.5 or smaller, for example, where Tp is the thickness of the piezoelectric layer 5 corresponding to the overlapping region A, and p is the center-to-center distance between adjacent first and second electrode fingers 18 and 19. With this arrangement, a bulk wave of the thickness shear mode can be suitably excited.

In the region where the adjacent first and second electrode fingers 18 and 19 overlap each other in the electrode-finger perpendicular direction, the center-to-center region between first and second electrode fingers 18 and 19 is an excitation region C. That is, the overlapping region A includes multiple excitation regions C. The overlapping region A and the excitation region C are regions of the piezoelectric layer 5 that are defined based on the configuration of the IDT electrode 8. In each excitation region C, a bulk wave of the thickness shear mode is excited. The acoustic wave resonator 1 may be configured to utilize a Lamb wave. In this case, the excitation region is equivalent to the overlapping region A.

In the first example embodiment, the cut angles of the piezoelectric layer 5 are Z-Y angles. The Z-Y angles refer to that the Z axis of the crystal of the piezoelectric layer 5 is perpendicular to the first main surface 5a of the piezoelectric layer 5, and the Y axis of the crystal is parallel to the electrode-finger perpendicular direction. In the first example embodiment, the crystal of the piezoelectric layer 5 is made of LiNbO₃. However, the material and the cut angles of the piezoelectric layer 5 are not limited to those described above.

FIG. 4 is a schematic elevational cross-sectional view of a pair of electrode fingers and its surrounding portion in the acoustic wave resonator in the first example embodiment.

Hereinafter, the thickness of the first dielectric film 6 that overlaps the overlapping region A in a plan view is denoted by Td_f. More specifically, the thickness Td_f is the thickness of the first dielectric film 6 positioned between electrode fingers. The thickness of the second dielectric film 7 that overlaps the overlapping region A in a plan view is denoted by Td_b.

In the first example embodiment, the fractional bandwidth is about 8.5% or higher and about 0.322<(Td_f/Tp)+(Td_b/Tp)<about 0.786 and |(Td_f/Tp)−(Td_b/Tp)|<about 0.196, for example. When the filter device is used as a communication device and has a wide passband, high-order modes, such as the second- and third-order modes, are likely to degrade the communication quality. In contrast, in the first example embodiment, the filter device 10 configured as described above can widen the passband and also suppress the occurrence of the second- and third-order modes in the acoustic wave resonator 1. The effect of suppressing the second- and third-order modes will be discussed below in detail by comparing the first example embodiment with a comparative example. Then, it will be demonstrated that, when the fractional bandwidth is about 8.5% or higher, for example, problems caused by high-order modes are likely to arise.

The comparative example is different from the first example embodiment in that 0.786<(Td_f/Tp)+(Td_b/Tp). The impedance frequency characteristics of the first example embodiment and the comparative example were derived by a FEM (Finite Element Method) simulation. Example design parameters of the acoustic wave resonator 1 in the first example embodiment are as follows. The electrode finger pitch defined by the design parameters are the center-to-center distance between adjacent first and second electrode fingers 18 and 19 in the electrode-finger perpendicular direction. The electrode finger width is a dimension of the electrode finger along the electrode-finger perpendicular direction.
Piezoelectric layer: made of LiNbO₃ having Z-Y cut angles and having a 356-nm thickness Tp
First dielectric film: made of SiO₂ and an 89-nm thickness Td_f
Second dielectric film: made of SiO₂ and an 89-nm thickness Td_b
IDT electrode: constituted by a Ti layer having a 10-nm thickness and an Al layer having a 100-nm thickness in this order as seen from the piezoelectric layer
Electrode finger pitch: 4 μm
Electrode finger width: 0.8 μm

$$Td\_f / Tp : 0.25$$

$$Td\_b / Tp : 0.25$$

$$( Td\_f / Tp ) + ( Td\_b / Tp ) : 0.5$$

$$\vert ( Td\_f / Tp ) - ( Td\_b / Tp ) \vert : 0$$

The design parameters of the acoustic wave resonator in the comparative example are as follows.
Piezoelectric layer: made of LiNbO₃ having Z-Y cut angles and having a 294-nm thickness Tp
First dielectric film: made of SiO₂ and a 132-nm thickness Td_f
Second dielectric film: made of SiO₂ and a 132-nm thickness Td_b
IDT electrode: constituted by a Ti layer having a 10-nm thickness and an Al layer having a 100-nm thickness in this order as seen from the piezoelectric layer
Electrode finger pitch: 4 μm
Electrode finger width: 0.8 μm

$$Td\_f / Tp : 0.45$$

$$Td\_b / Tp : 0.45$$

$$( Td\_f / Tp ) + ( Td\_b / Tp ) : 0.9$$

$$\vert ( Td\_f / Tp ) - ( Td\_b / Tp ) \vert : 0$$

The resonant frequency of the acoustic wave resonator 1 in an example of the first example embodiment to be compared with the comparative example is 4200 MHz. The acoustic wave resonator 1 can thus be used suitably as a parallel arm resonator in the filter device 10 having the n79 passband. The resonant frequency of the acoustic wave resonator in the comparative example is also 4200 MHz. The n79 passband is 4400 to 5000 MHz.

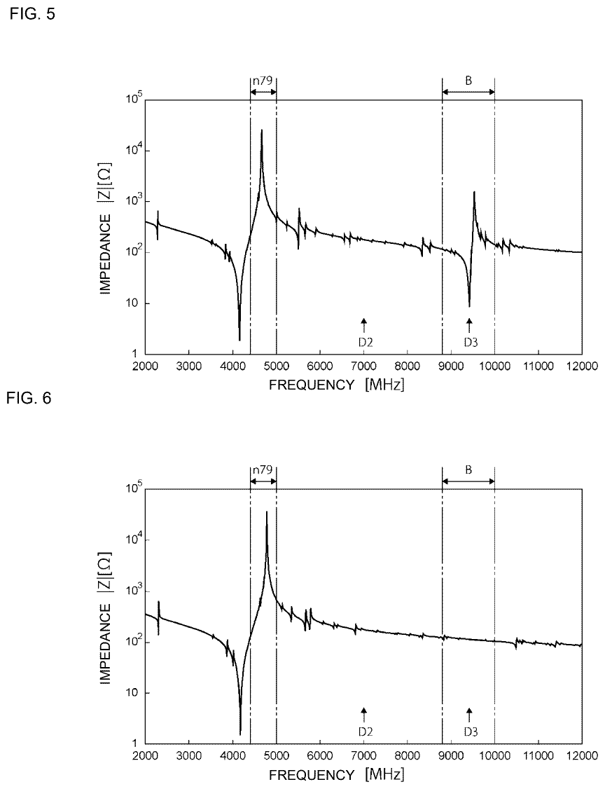

FIG. 5 is a graph illustrating the impedance frequency characteristics of the acoustic wave resonator in the comparative example. FIG. 6 is a graph illustrating the impedance frequency characteristics of the acoustic wave resonator in the first example embodiment. In FIGS. 5 and 6, the impedance frequency characteristics in the n79 passband are shown. In FIGS. 5 and 6, the impedance frequency characteristics in the frequency band B of 8800 to 10000 MHz, which is twice as high as the n79 passband, are also shown. In FIGS. 5 and 6, the arrow D2 indicates a frequency range in which the second-order mode occurs, while the arrow D3 indicates a frequency range in which the third-order mode occurs.

As illustrated in FIG. 5, in the comparative example, the second-order mode in the vicinity of 7000 MHz is suppressed, while a large spurious emission caused by the third-order mode occurs in the vicinity of 9500 MHz. This spurious emission occurs in the frequency range at the center of the frequency band B, which is twice as high as the n79 passband. If the acoustic wave resonator in the comparative example is used for a filter device having the n79 passband as a parallel arm resonator, the attenuation characteristics deteriorate near the frequency band B. This causes the degradation of the communication quality of the filter device.

In contrast, FIG. 6 shows that, in the first example embodiment, not only the second-order mode, but also the third-order mode is also suppressed. The acoustic wave resonator 1 in the first example embodiment is used for the filter device 10 having the n79 passband as a parallel arm resonator. The attenuation characteristics near the frequency band B can thus be improved. Hence, when the filter device 10 is used as a communication device, the communication quality is less likely to deteriorate.

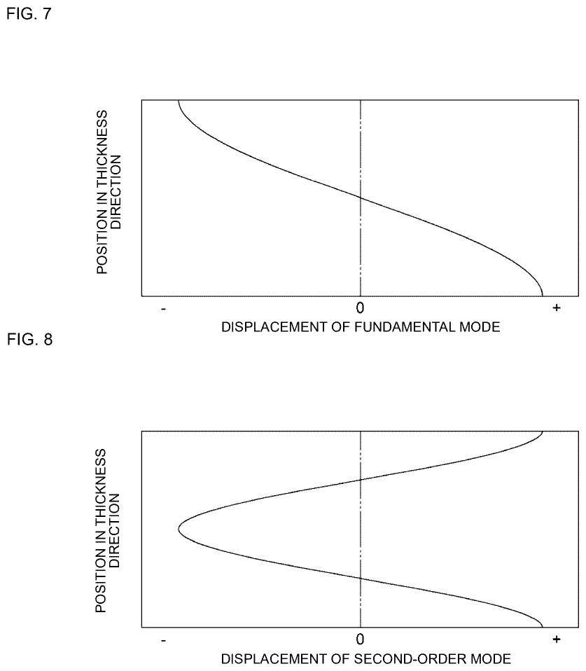

As described above, the acoustic wave resonator 1 can suppress the second- and third-order modes. The reason for this will be explained below. As shown in FIG. 2, the acoustic wave resonator 1 includes a multilayer section 9. The multilayer section 9 is specifically a portion in which the piezoelectric layer 5, the first dielectric film 6, and the second dielectric film 7 are stacked on each other. In the first example embodiment, the multilayer section 9 includes portions that do not overlap the IDT electrode 8 in a plan view. The multilayer section 9 includes multiple inter-electrode-finger central portions 9a. Specifically, the inter-electrode-finger central portion 9a is a central portion between electrode fingers. In FIGS. 7 through 12, the displacement/stress distributions of the individual modes at a given instant in the inter-electrode-finger central portion 9a of the multilayer section 9 are shown.

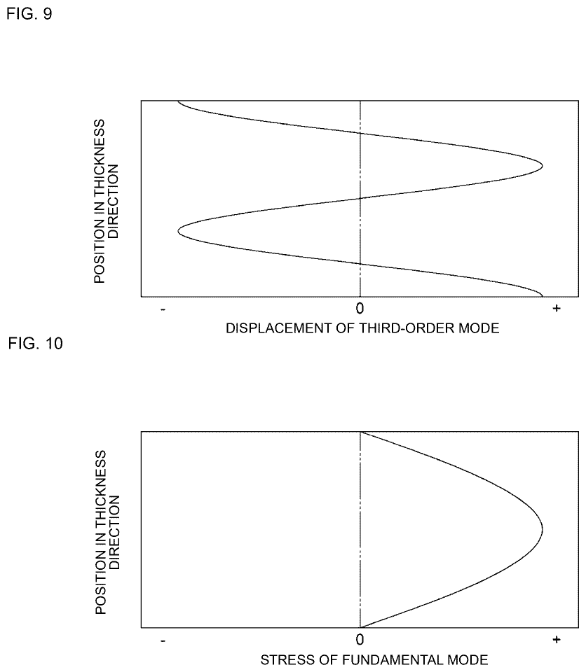

FIG. 7 is a schematic diagram illustrating the thickness-direction displacement distribution of the fundamental mode in the inter-electrode-finger central portion of the multilayer section in the first example embodiment. FIG. 8 is a schematic diagram illustrating the thickness-direction displacement distribution of the second-order mode in the inter-electrode-finger central portion of the multilayer section in the first example embodiment. FIG. 9 is a schematic diagram illustrating the thickness-direction displacement distribution of the third-order mode in the inter-electrode-finger central portion of the multilayer section in the first example embodiment.

In FIGS. 7 through 9, the horizontal axis indicates the magnitude of displacement, and the vertical axis indicates the position of the multilayer section 9 in the thickness direction. For the sake of convenience, between the two opposite directions perpendicular to the thickness direction of the multilayer section 9, the positive sign+is assigned to the displacement in one direction, while the negative sign−is assigned to the displacement in the other direction. More specifically, the right side in FIGS. 7 through 9 is set to the positive sign+, while the left side in FIGS. 7 through 9 is set to the negative sign−. The upper edge of the vertical axis in FIGS. 7 through 9 corresponds to the surface of the first dielectric film 6, while the lower edge thereof corresponds to the surface of the second dielectric film 7. In FIGS. 10 through 14, the upper edge and the lower edge of the vertical axis are defined in the same manner.

As shown in FIG. 7, the fundamental mode is a wave whose displacement direction is perpendicular to the thickness direction of the multilayer section 9. The fundamental mode in the first example embodiment is the fundamental thickness shear mode. Likewise, as shown in FIGS. 8 and 9, the second-order mode and the third-order mode are also a wave whose displacement direction is perpendicular to the thickness direction of the multilayer section 9. In other words, the fundamental mode, second-order mode, and third-order mode in the first example embodiment are thickness-direction modes. As the order of the mode is higher, the wavelength becomes shorter. More specifically, in the first example embodiment, a half-wavelength of the fundamental mode corresponds to the total thickness of the multilayer section 9. A full-wavelength of the second-order mode corresponds to the total thickness of the multilayer section 9. One and half wavelengths of the third-order mode correspond to the total thickness of the multilayer section 9.

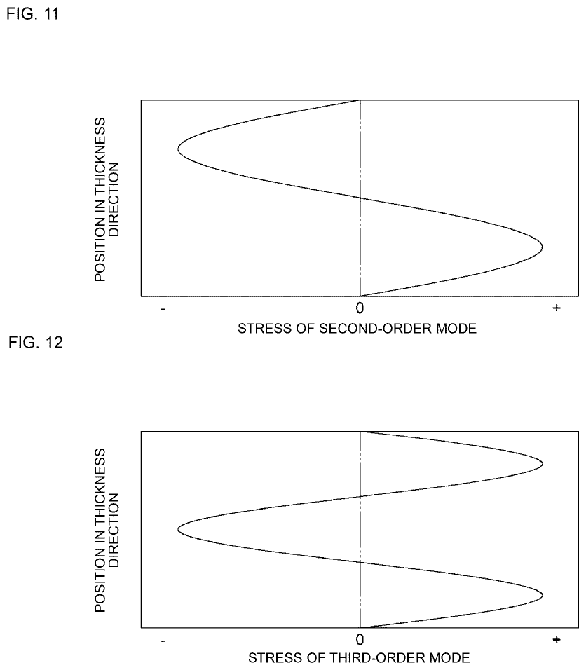

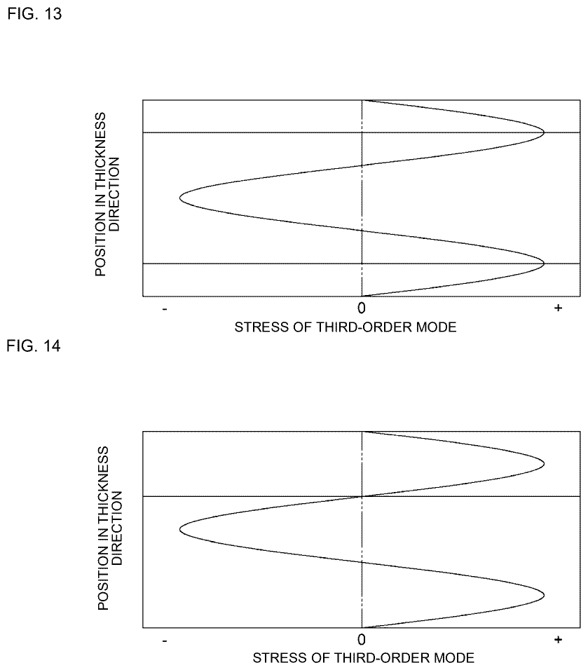

FIG. 10 is a schematic diagram illustrating the thickness-direction stress distribution of the fundamental mode in the inter-electrode-finger central portion of the multilayer section in the first example embodiment. FIG. 11 is a schematic diagram illustrating the thickness-direction stress distribution of the second-order mode in the inter-electrode-finger central portion of the multilayer section in the first example embodiment. FIG. 12 is a schematic diagram illustrating the thickness-direction stress distribution of the third-order mode in the inter-electrode-finger central portion of the multilayer section in the first example embodiment. In FIGS. 10 through 12, the horizontal axis indicates the magnitude of stress, and the vertical axis indicates the position of the multilayer section 9 in the thickness direction. For the sake of convenience, between the stresses that generate the thickness shear mode within the multilayer section 9, the positive sign+is assigned to the stress that generates one type of deformation, while the negative sign−is assigned to the stress that generates the other type of deformation. More specifically, the right side in FIGS. 10 through 12 is set to the positive sign+, while the left side in FIGS. 10 through 12 is set to the negative sign−. The same applies to FIGS. 13 and 14, which will be discussed later.

As illustrated in FIGS. 10 through 12, the stress distribution in the thickness direction of each mode is represented by a waveform. The stress waveform of the fundamental mode corresponds to a waveform that is out of phase with the displacement waveform of the fundamental mode shown in FIG. 7. That is, the wavelength of the stress waveform of the fundamental mode is identical to the wavelength of the displacement waveform of the fundamental mode. The same applies to the second- and third-order modes.

As shown in FIG. 11, the stress waveform of the second-order mode is distributed both in the positive direction and in the negative direction. In the stress distribution of the second-order mode, the integral value of the stress in the positive direction and that in the negative direction are the same. Accordingly, the integral value of the stress of the second-order mode in the overall thickness direction of the multilayer section 9 is about 0.

As shown in FIG. 12, the stress waveform of the third-order mode is also distributed both in the positive direction and in the negative direction. However, the integral value of the stress of the third-order mode in the overall thickness direction of the multilayer section 9 is not 0.

The integral value of the stress distribution in the thickness direction within the piezoelectric layer is proportional to the electromechanical coupling coefficient. This is described in “J. Kaitila, Review of Wave Propagation in BAW Thin Film Devices Progress and Prospects, Proc. IEEE Ultrasonics Symposium Proceedings, 2007, pp. 120-129”.

The integral value of the stress in each mode within the piezoelectric layer 5 varies depending on the relationship between the thickness Tp of the piezoelectric layer 5, the thickness Td_f of the first dielectric film 6, and the thickness Td_b of the second dielectric film 7. The above-described design parameters of the first example embodiment show that Td_f=Td_b. In this case, the integral value of the stress of the second-order mode within the piezoelectric layer 5 is about 0. Accordingly, the electromechanical coupling coefficient of the second-order mode is small. In the first example embodiment, therefore, the second-order mode can be suppressed as illustrated in FIG. 6. That is, theoretically, the second-order mode is not excited in the first example embodiment.

The above-described design parameters of the first example embodiment show that Td_f=Td_b=0.25Tp. Two-thirds of the total thickness of the multilayer section 9 is the thickness Tp of the piezoelectric layer 5. In this case, (Td_f/Tp)+(Td_b/Tp)=0.5. This can suppress the third-order mode. This will be explained below.

FIG. 13 is a schematic diagram illustrating the thickness-direction stress distribution of the third-order mode in the inter-electrode-finger central portion of the multilayer section when the third-order mode is suppressed. The solid line extending in the left-right direction on the upper side in FIG. 13 indicates the boundary between the piezoelectric layer 5 and the first dielectric film 6. The same applies to FIG. 14. The solid line extending in the left-right direction on the lower side in FIG. 13 indicates the boundary between the piezoelectric layer 5 and the second dielectric film 7.

The total thickness of the multilayer section 9 corresponds to one and half wavelengths of the stress waveform of the third-order mode. One wavelength, which is two thirds of one and half wavelengths, corresponds to the thickness of the piezoelectric layer 5. This situation is illustrated in FIG. 13. In this case, the integral value of the stress of the third-order mode within the piezoelectric layer 5 is about 0. Accordingly, the electromechanical coupling coefficient of the third-order mode is small. As a result, the third-order mode can be suppressed in the first example embodiment, as illustrated in FIG. 6.

The third-order mode can be suppressed in a case other than when (Td_f/Tp)+(Td_b/Tp)=about 0.5. For example, when (Td_f/Tp)+(Td_b/Tp) is approximately 0.5, the thickness of the piezoelectric layer 5 corresponds to approximately one wavelength of the stress waveform of the third-order mode. In this case, the absolute value of the integral of the stress of the third-order mode within the piezoelectric layer 5 is small. Accordingly, the electromechanical coupling coefficient of the third-order mode can be made small, thus suppressing the third-order mode.

FIG. 14 illustrates, as a reference example, the stress distribution of the third-order mode when the second dielectric film 7 is not provided, and only the first dielectric film 6 is provided. In the reference example, the multilayer section includes the first dielectric film 6 and the piezoelectric layer 5. Td_f=about 0.5Tp and Td_b=0, and (Td_f/Tp)+(Td_b/Tp)=about 0.5. In the reference example, too, two thirds of the total thickness of the multilayer section is the thickness Tp of the piezoelectric layer 5. The third-order mode can thus be suppressed. In the reference example, however, it is difficult to suppress the second-order mode.

As described above, when (Td_f/Tp)+(Td_b/Tp) is approximately 0.5, the third-order mode can be suppressed regardless of the relationship between the thickness Td_f of the first dielectric film 6 and the thickness Td_b of the second dielectric film 7.

In actuality, the integral value of the stress of the third-order mode within the piezoelectric layer 5 is influenced by the differences in properties, such as the density and the elastic modulus, of the piezoelectric layer 5 and the first and second dielectric films 6 and 7. Hence, the integral value may become 0 when (Td_f/Tp)+(Td_b/Tp) is not about 0.5.

Similarly to the third-order mode, when the absolute value of the integral of the stress of another high-order mode within the piezoelectric layer 5 is small, that high-order mode can also be suppressed. The conditions that the integral value becomes 0 in the fourth- through eighth-order modes will be discussed below.

The integral value of the stress of the fourth-order mode becomes 0 when Td_f=Td_b or (Td_f/Tp)+(Td_b/Tp) is 1. The integral value of the stress of the fifth-order mode becomes 0 when (Td_f/Tp)+(Td_b/Tp) is about 0.25 or about 1.5, for example. The integral value of the stress of the sixth-order mode becomes 0 when Td_f=Td_b or (Td_f/Tp)+(Td_b/Tp) is about 0.5 or about 2, for example. The integral value of the stress of the seventh-order mode becomes 0 when (Td_f/Tp)+(Td_b/Tp) is about 0.167, about 0.75, or about 2.5, for example. The integral value of the stress of the eighth-order mode becomes 0 when Td_f=Td_b or (Td_f/Tp)+(Td_b/Tp) is about 0.333, about 1, or about 3, for example.

The above-described design parameters of the first example embodiment show that Td_f=Td_b. In the first example embodiment, therefore, not only the second- and third-order modes, but also the fourth-, sixth-, and eighth-order modes can be suppressed.

As shown in FIG. 10, the stress of the fundamental mode is distributed only in the positive direction. As the ratio of the thickness Tp of the piezoelectric layer 5 to the total thickness of the multilayer section 9 is larger, the integral value of the stress of the fundamental mode within the piezoelectric layer 5 becomes greater. As a result, the electromechanical coupling coefficient of the fundamental mode can be increased.

As illustrated in FIG. 10, the absolute value of the stress of the fundamental mode becomes smaller as the position of the multilayer section 9 becomes closer to the surface of the first dielectric film 6. Likewise, the absolute value of the stress of the fundamental mode becomes smaller as the position of the multilayer section 9 becomes closer to the surface of the second dielectric film 7. Accordingly, as the thickness Td_f of the first dielectric film 6 becomes closer to the thickness Td_b of the second dielectric film 7, the integral value of the stress in the fundamental mode within the piezoelectric layer 5 becomes greater. As a result, the electromechanical coupling coefficient of the fundamental mode can be increased.

The above-described design parameters of the first example embodiment show that Td_f=Td_b. In the first example embodiment, therefore, the second- and third-order modes can be suppressed, and the fundamental mode can be excited strongly and preferentially.

The relationships between the thickness Tp of the piezoelectric layer 5, the thickness Td_f of the first dielectric film 6, and the thickness Td_b of the second dielectric film 7 that can suppress the second- and third-order modes were derived. In greater details, the admittance frequency characteristics of the acoustic wave resonator 1 were derived based on the formula shown in “V. Plessky, et al. A formula for the admittance of laterally excited bulk wave resonators (XBARs), Electronics Letters 57.20 (2021): 773-775”. By using this formula, the admittance frequency characteristics including the contribution of the fundamental mode and higher-order modes, such as the second- and third-order modes, in the thickness direction can be derived.

When deriving the admittance frequency characteristics, certain measures were taken so that the resonant frequency of the fundamental mode matches the resonant frequency in the impedance frequency characteristics shown in FIG. 6. More specifically, the thickness Tp of the piezoelectric layer 5, the thickness Td_f of the first dielectric film 6, and the thickness Td_b of the second dielectric film 7 were adjusted.

The resonant frequency Fr and the anti-resonant frequency Fa of each of the fundamental mode, the second-order mode, and the third-order mode in the admittance frequency characteristics were determined. Then, the electromechanical coupling coefficient K²_{eff} of each mode was calculated by the following expression from the resonant frequency Fr and the anti-resonant frequency Fa of the corresponding mode.

$${K}_{eff}^{2} = \frac{\frac{π}{2} \frac{{F}_{r}}{{F}_{a}}}{tan ( \frac{π}{2} \frac{{F}_{r}}{{F}_{a}} )} \qquad [ Math . 1 ]$$

The relationship between the electromechanical coupling coefficient K²_{eff} of each mode and the ratio Td_f/Tp of the thickness Td_f of the first dielectric film 6 to the thickness Tp of the piezoelectric layer 5 and also the relationship between the electromechanical coupling coefficient K²_{eff} of each mode and the ratio Td_b/Tp of the thickness Td_b of the second dielectric film 7 to the thickness Tp of the piezoelectric layer 5 were derived.

First, under the condition that the second-order mode was not excited, the relationship between the ratio Td_f/Tp and the electromechanical coupling coefficient K²_{eff} of the third-order mode was derived. More specifically, in a state in which Td_f/Tp=Td_b/Tp, the electromechanical coupling coefficient K²_{eff} of the third-order mode was calculated every time the ratio Td_f/Tp and the ratio Td_b/Tp were changed.

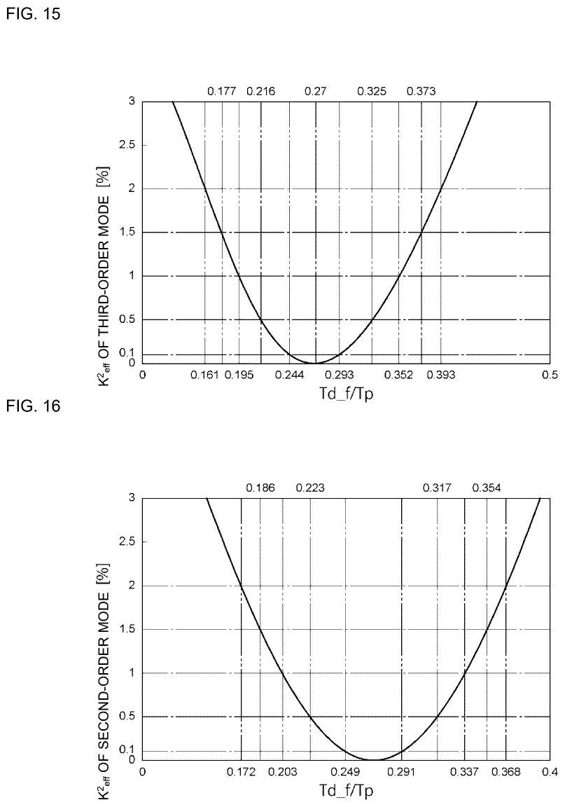

FIG. 15 is a graph illustrating the relationship between the ratio Td_f/Tp and the electromechanical coupling coefficient K²_{eff} of the third-order mode when Td_f=Td_b. Since Td_f=Td_b, the relationship between the ratio Td_b/Tp and the electromechanical coupling coefficient K²_{eff} of the third-order mode is also represented by the relationship shown in FIG. 15.

As illustrated in FIG. 15, when the ratio Td_f/Tp is approximately 0.27, for example, the electromechanical coupling coefficient K²_{eff} of the third-order mode reaches the local minimum value. Since Td_f=Td_b, when the ratio Td_f/Tp and the ratio Td_b/Tp are approximately 0.27 and when (Td_f/Tp)+(Td_b/Tp) is approximately 0.54, for example, the electromechanical coupling coefficient K²_{eff} of the third-order mode reaches the local minimum value. More specifically, the electromechanical coupling coefficient K²_{eff} almost becomes 0. In this case, substantially no third-order mode is excited. Since Td_f=Td_b, the second-order mode is not excited, either.

There are some cases, however, in which the electromechanical coupling coefficient K²_{eff} of the third-order mode can be reduced even when (Td_f/Tp)+(Td_b/Tp) is not about 0.54, for example. The range of (Td_f/Tp)+(Td_b/Tp) that can reduce the electromechanical coupling coefficient K²_{eff} of the third-order mode and can accordingly suppress the third-order mode will be discussed below.

When about 0.322<(Td_f/Tp)+(Td_b/Tp)<about 0.786, the electromechanical coupling coefficient K²_{eff} of the third-order mode can be reduced to less than about 2%, for example. When about 0.354<(Td_f/Tp)+(Td_b/Tp)<about 0.746, the electromechanical coupling coefficient K²_{eff} of the third-order mode can be reduced to less than about 1.5%, for example. When about 0.39<(Td_f/Tp)+(Td_b/Tp)<about 0.704, the electromechanical coupling coefficient K²_{eff} of the third-order mode can be reduced to less than about 1%, for example. When about 0.432<(Td_f/Tp)+(Td_b/Tp)<about 0.65, the electromechanical coupling coefficient K²_{eff} of the third-order mode can be reduced to less than about 0.5%, for example. When about 0.488<(Td_f/Tp)+(Td_b/Tp)<about 0.586, the electromechanical coupling coefficient K²_{eff} of the third-order mode can be reduced to less than about 0.1%, for example.

Under the condition that substantially no third-order mode was excited, the relationship between the ratio Td_f/Tp and the electromechanical coupling coefficient K²_{eff} of the second-order mode was derived. More specifically, in a state in which (Td_f/Tp)+(Td_b/Tp)=about 0.54, for example, the electromechanical coupling coefficient K²_{eff} of the second-order mode was calculated every time the ratio Td_f/Tp and the ratio Td_b/Tp were changed.

FIG. 16 is a graph illustrating the relationship between the ratio Td_f/Tp and the electromechanical coupling coefficient K²_{eff} of the second-order mode when (Td_f/Tp)+(Td_b/Tp)=0.54.

As illustrated in FIG. 16, when about 0.172<Td_f/Tp<about 0.368, the electromechanical coupling coefficient K²_{eff} of the second-order mode can be reduced to less than about 2%, for example. The range of the ratio Td_b/Tp of the thickness Td_b of the second dielectric film 7 to the thickness Tp of the piezoelectric layer 5 is about 0.172<Td_b/Tp<about 0.368 since (Td_f/Tp)+(Td_b/Tp)=about 0.54, for example. In this range of the ratio Td_f/Tp and the ratio Td_b/Tp, |(Td_f/Tp)−(Td_b/Tp)|<about 0.196, for example. Within this range, the electromechanical coupling coefficient K²_{eff} of the second-order mode can be reduced to less than about 2%, for example. As a result, the second-order mode can be suppressed.

The range of |(Td_f/Tp)−(Td_b/Tp)| that can effectively reduce the electromechanical coupling coefficient K²_{eff} of the second-order mode and can thus effectively suppress the second-order mode will be discussed below.

When about 0.186<Td_f/Tp<about 0.354, |(Td_f/Tp)−(Td_b/Tp)|<about 0.168 and the electromechanical coupling coefficient K²_{eff} of the second-order mode can be reduced to about 1.5%, for example. When about 0.203<Td_f/Tp<about 0.337, |(Td_f/Tp)−(Td_b/Tp)|<about 0.134 and the electromechanical coupling coefficient K²_{eff} of the second-order mode can be reduced to less than about 1%, for example. When about 0.223<Td_f/Tp<about 0.317, |(Td_f/Tp)−(Td_b/Tp)|<about 0.094 and the electromechanical coupling coefficient K²_{eff} of the second-order mode can be reduced to less than about 0.5%, for example. When about 0.249<Td_f/Tp<about 0.291, |(Td_f/Tp)−(Td_b/Tp)|<about 0.042 and the electromechanical coupling coefficient K²_{eff} of the second-order mode can be reduced to less than about 0.1%, for example.

The results based on FIGS. 15 and 16 show that the second-order mode and the third-order mode can be suppressed in the first example embodiment. That is, in the first example embodiment, about 0.322<(Td_f/Tp)+(Td_b/Tp)<about 0.786 and |(Td_f/Tp)−(Td_b/Tp)|<about 0.196, for example. With these conditions, the electromechanical coupling coefficients K²_{eff} of the second- and third-order modes can be reduced to less than about 2%, for example. As a result, the second- and third-order modes can be reduced or prevented.

It is preferable that about 0.354<(Td_f/Tp)+(Td_b/Tp)<about 0.746 and |(Td_f/Tp)−(Td_b/Tp)|<about 0.168, for example. This can reduce the electromechanical coupling coefficients K²_{eff} of the second- and third-order modes to less than about 1.5%, for example.

It is more preferable that about 0.39<(Td_f/Tp)+(Td_b/Tp)<about 0.704 and |(Td_f/Tp)−(Td_b/Tp)|<about 0.134, for example. This can reduce the electromechanical coupling coefficients K²_{eff} of the second- and third-order modes to less than about 1%, for example.

It is even more preferable that about 0.432<(Td_f/Tp)+(Td_b/Tp)<about 0.65 and |(Td_f/Tp)−(Td_b/Tp)|<about 0.094, for example. This can reduce the electromechanical coupling coefficients K²_{eff} of the second- and third-order modes to less than about 0.5%, for example.

It is even more preferable that about 0.488<(Td_f/Tp)+(Td_b/Tp)<about 0.586 and |(Td_f/Tp)−(Td_b/Tp)|<about 0.042, for example. This can reduce the electromechanical coupling coefficients K²_{eff} of the second- and third-order modes to less than about 0.1%, for example.

In the above-described preferable ranges, the electromechanical coupling coefficient K²_{eff} of the fundamental mode is as high as about 23%, more specifically, about 23% or higher, for example. Acoustic wave devices according to example embodiments of the present invention can thus be suitably used as an acoustic wave resonator of a filter device having a wide passband for 5G, for example.

A typical radio-frequency communication filter is required to exhibit high attenuation characteristics in a frequency band near an integral multiple of the passband. For example, the frequency band B in FIG. 5 is a frequency band that is twice as high as the passband. If, for example, the third-order mode occurs in the frequency band B, the attenuation characteristics in the frequency band B deteriorate. This causes the degradation of the communication quality of the radio-frequency filter. Whether the third-order mode is likely to occur in the frequency band B depends on the fractional bandwidth. Additionally, the ratio of the resonant frequency of the third-order mode to that of the fundamental mode is influenced by certain factors, such as the ratio Td_f/Tp. The ratio of the resonant frequency of the third-order mode to that of the fundamental mode can be represented by Fr3/Fr1, where Fr1 is the resonant frequency of the fundamental mode, and Fr3 is the resonant frequency of the third-order mode.

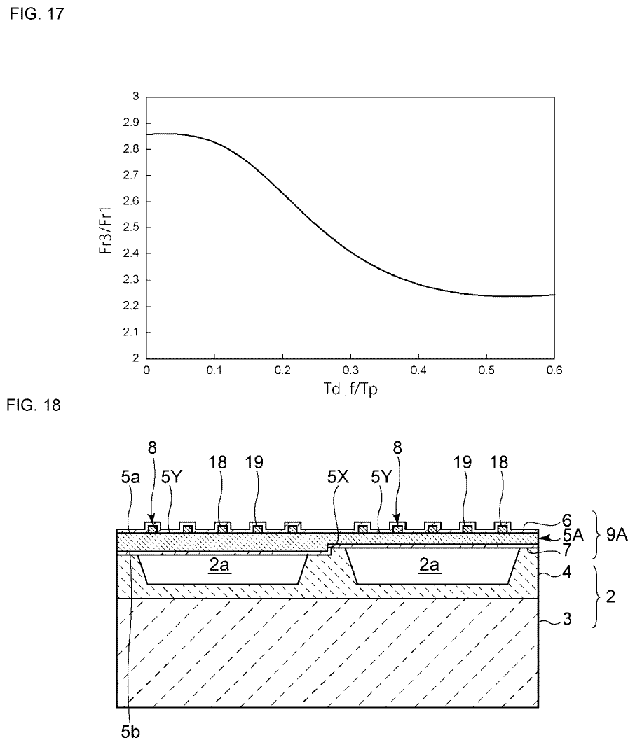

FIG. 17 is a graph illustrating the relationship between the ratio Td_f/Tp and the ratio Fr3/Fr1.

The anti-resonant frequency of the fundamental mode of the parallel arm resonator is located within the passband of the filter device. The resonant frequency Fr1 of the fundamental mode of the parallel arm resonator is slightly lower than the lower limit FL of the passband of the filter device. The resonant frequency Fr3 of the third-order mode is about 2.2 to about 2.9 times the resonant frequency Fr1 of the fundamental mode, for example, as illustrated in FIG. 17. Accordingly, the third-order mode occurs in a frequency range at least twice as high as the lower limit FL of the passband of the filter device. When the passband is relatively narrow, the third-order mode occurs in a frequency range at least twice as high as the upper limit FH of the passband. That is, the third-order mode does not occur in the frequency band B. As a result, when the filter device is used as a communication device, the communication quality is unlikely to deteriorate.

In contrast, when the passband is relatively wide, the third-order mode occurs in a frequency range lower than the frequency twice as high as the upper limit FH of the passband. For example, a 5G-support radio-frequency filter device is required to have a wide passband. When the fractional bandwidth is about 8.5% or higher, for example, the third-order mode is likely to occur in the frequency band B. As described above, decreased attenuation characteristics in the frequency band B degrade the communication quality. Thus, especially when the fractional bandwidth of the filter device is about 8.5% or higher, for example, it is necessary to suppress the third-order mode. This will be explained below in detail.

As an examination example, the lower limit FL of the passband of the filter device was set to 4400 MHz, and the bandwidth of the passband was changed by varying the upper limit FH. The bandwidth R of the passband can be represented by R=FH−FL. The difference between the lower limit FL of the passband and the resonant frequency of the fundamental mode of the parallel arm resonator was set to a value equivalent to 0.33 times the bandwidth R. That is, |FL−Fr1|/R=0.33.

In the comparative example shown in FIG. 5, the resonant frequency Fr1 of the fundamental mode of the parallel arm resonator is 4200 MHz, and the resonant frequency Fr3 of the third-order mode is 9500 MHz. In this case, the resonant frequency Fr3 of the third-order mode is 2.26 times the resonant frequency Fr1 of the fundamental mode. Likewise, in the above-described examination, Fr3/Fr1 was set to 2.26. In the examination, however, the resonant frequency Fr1 of the fundamental mode was not limited to 4200 MHz.

Under the conditions that FL is 4400 MHz, |FL−Fr1|/R is about 0.33, and Fr3/Fr1 is about 2.26, for example, when the resonant frequency Fr3 of the third-order mode of the parallel arm resonator coincides with the frequency that is twice the upper limit FH of the passband, the upper limit FH is 4817 MHz. In this case, the fractional bandwidth is about 9%, for example. When the fractional bandwidth is wider, the resonant frequency Fr3 of the third-order mode is lower than the frequency twice the upper limit FH of the passband. The frequency twice the upper limit FH of the passband is the highest frequency in the frequency band B. This means that, when the fractional bandwidth is about 9% or higher, for example, the third-order mode occurs in the frequency band B. In reality, however, the above-described individual frequencies vary depending on the temperature changes or manufacturing variations. It is thus necessary to suppress high-order modes, in particular, the third-order mode, when the fractional bandwidth is about 8.5% or higher, for example.

In the first example embodiment, the fractional bandwidth of the filter device 10 is about 8.5% or higher, for example, and the second- and third-order modes can be suppressed in the acoustic wave resonator 1. As a result, the filter device 10 can be suitably used as a 0147-support filter device and the communication performance is unlikely to deteriorate.

The configuration of the first example embodiment will be described below in greater detail.

As illustrated in FIG. 1, the filter device 10 includes a first signal terminal 13, a second signal terminal 14, multiple series arm resonators, and multiple parallel arm resonators. The first signal terminal 13 is connected to an input potential. The second signal terminal 14 is connected to an output potential. Conversely, the first signal terminal 13 may be connected to the output potential, while the second signal terminal 14 may be connected to the input potential. The first and second signal terminals 13 and 14 may be electrode pads or as wiring traces.

Specifically, the series arm resonators are series arm resonators S1 through S5. The series arm resonators are connected in series with each other between the first signal terminal 13 and the second signal terminal 14. The series arm resonators S1, S2, S3, S4, and S5 are arranged in this order as seen from the first signal terminal 13.

Specifically, the parallel arm resonators are the acoustic wave resonator 1 and parallel arm resonators P2 through P4. The acoustic wave resonator 1 is connected between a ground potential and a node between the series arm resonators S1 and S2. The parallel arm resonator P2 is connected between a ground potential and a node between the series arm resonators S2 and S3. The parallel arm resonator P3 is connected between a ground potential and a node between the series arm resonators S3 and S4. The parallel arm resonator P4 is connected between a ground potential and a node between the series arm resonators S4 and S5.

In the design of a ladder filter, the resonant frequency of series arm resonators and that of parallel arm resonators are made different from each other. This can obtain a desired passband and other characteristics. Additionally, by making the resonant frequencies of the series arm resonators different from each other or the resonant frequencies of the parallel arm resonators different from each other, the filter characteristics can be improved.

In the filter device 10 shown in FIG. 2, the IDT electrode 8, which serves as a function electrode, is disposed on the piezoelectric layer 5, thus providing an acoustic wave resonator. The filter device 10 configured in this manner may be called a chip. It is sufficient that, within a single chip, the resonant frequency of series arm resonators be different from that of parallel arm resonators.

In an acoustic wave resonator according to an example embodiment of the present invention utilizing a bulk wave of the thickness shear mode, the resonant frequency can be adjusted by, for example, changing at least one of the thicknesses of the piezoelectric layer 5, the first dielectric film 6, and the second dielectric film 7. Within a single chip, multiple acoustic wave resonators may be provided in which the thickness of the piezoelectric layer 5, the first dielectric film 6, or the second dielectric film 7 is different among the acoustic wave resonators. As a result, at least, the resonant frequency of the series arm resonators and that of the parallel arm resonators can be made different from each other.

As described above, multiple acoustic wave resonators may be provided in which the thickness of the piezoelectric layer 5, the first dielectric film 6, or the second dielectric film 7 is different among the acoustic wave resonators. An example of such acoustic wave resonators will be described below through illustration of first through third modified examples of the first example embodiment. In the specification, if the first example embodiment shown in FIG. 2 is taken as an example, the thickness of the piezoelectric layer 5 in each acoustic wave resonator is the thickness of the piezoelectric layer 5 corresponding to the inter-electrode-finger central portion 9a of the multilayer section 9. Likewise, the thickness of each of the first dielectric film 6 and the second dielectric film 7 in each acoustic wave resonator is the thickness of the first dielectric film 6 or the second dielectric film 7 corresponding to the inter-electrode-finger central portion 9a of the multilayer section 9.

The circuit configurations of the first through third modified examples are similar to that of the first example embodiment. In the first through third modified examples, the fractional bandwidth is about 8.5% or higher, and all the acoustic wave resonators satisfy the conditions that about 0.322<(Td_f/Tp)+(Td_b/Tp)<about 0.786 and |(Td_f/Tp)−(Td_b/Tp)|<about 0.196, for example. With this configuration, in the first through third modified examples, as well as in the first example embodiment, a wide bandwidth can be implemented, and also, the second- and third-order modes can be suppressed in the acoustic wave resonators.

Alternatively, at least one acoustic wave resonator may satisfy the conditions that about 0.322<(Td_f/Tp)+(Td_b/Tp)<about 0.786 and |(Td_f/Tp)−(Td_b/Tp)|<about 0.196, for example.

In the first modified example illustrated in FIG. 18, a piezoelectric layer 5A includes a thickness transition region 5X. The thickness transition region 5X is a region where the thickness of the piezoelectric layer is changed. In the first modified example, multiple acoustic wave resonators share the same piezoelectric layer 5A. In FIG. 18, the thickness transition region 5X is provided at a position between adjacent acoustic wave resonators. With this arrangement, in FIG. 18, acoustic wave resonators including the piezoelectric layer 5A having different thicknesses are disposed adjacent to each other.

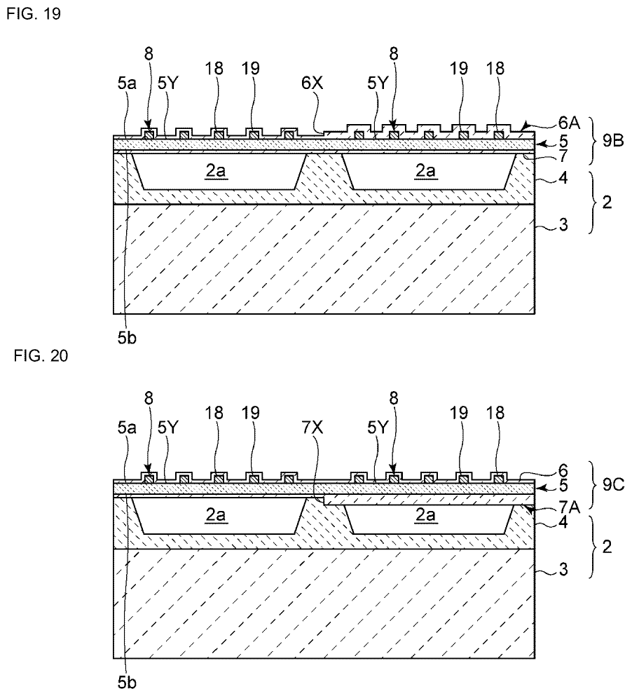

In the second modified example illustrated in FIG. 19, a first dielectric film 6A includes a thickness transition region 6X. In FIG. 19, acoustic wave resonators including the first dielectric film 6A having different thicknesses are disposed adjacent to each other. In the third modified example illustrated in FIG. 20, a second dielectric film 7A includes a thickness transition region 7X. In FIG. 20, acoustic wave resonators including the second dielectric film 7A having different thicknesses are disposed adjacent to each other.

In the first through third modified examples, each thickness transition region is configured as a step portion. The piezoelectric layer, the first dielectric film, or the second dielectric film have different thicknesses as a result of the thickness transition region serving as a boundary. The thickness transition region may be configured as a sloped surface that connects portions having different thicknesses.

The portions having different thicknesses of the piezoelectric layer 5A shown in FIG. 18 may be formed by film deposition or by etching, for example. The portions having different thicknesses of the first and second dielectric films 6A and 7A shown in FIGS. 19 and 20 may also be formed in a similar manner. A dielectric substance, such as silicon oxide, is easier to film-deposit or etch than a piezoelectric substance, such as lithium niobate. It is thus desirable that portions having different thicknesses be provided for the first dielectric film 6A and/or the second dielectric film 7A.

Hereinafter, the number of thicknesses of the piezoelectric layer, the first dielectric film, or the second dielectric film in the filter device will be called the number of thickness levels of the piezoelectric layer, the first dielectric film, or the second dielectric film. As the number of thickness levels of the piezoelectric layer of a filter device is greater, the filter characteristics of the filter device can be improved more effectively. The same applies to the first and second dielectric films.

On the other hand, however, if many thickness levels of the piezoelectric layer, the first dielectric film, or the second dielectric film are provided, the manufacturing process for the filter device becomes complicated, which may lead to increased costs. The number of thickness levels per filter device, namely, per chip, is desirably six or lower.

As shown in FIG. 18, the piezoelectric layer 5A of the first modified example includes a membrane 5Y. Specifically, the membrane 5Y is a portion of the piezoelectric layer 5A that overlaps a cavity 2a. If, for example, the thickness transition region 5X of the piezoelectric layer 5A is positioned at the membrane 5Y, the membrane 5Y may be damaged. The reason for this is that, if the thickness transition region 5X overlaps the cavity 2a in a plan view, a stress is likely to concentrate on the thickness transition region 5X. More specifically, with temperature changes or the application of a mechanical vibration or impact, a stress is likely to concentrate on the thickness transition region 5X. If a region vulnerable to a stress is positioned at the membrane 5Y in this manner, the membrane 5Y may be damaged.

As in the first modified example, it is desirable that the thickness transition region 5X be located within a region where a multilayer section 9A constituted by the piezoelectric layer 5A and the first and second dielectric films 6 and 7 contacts the insulating layer 4. This makes it unlikely to damage the membrane 5Y.

In the second and third modified examples shown in FIGS. 19 and 20, the piezoelectric layer 5 also includes a membrane 5Y. A stress is also likely to concentrate on the thickness transition region 6X shown in FIG. 19 and the thickness transition region 7X shown in FIG. 20. If, in the first and second dielectric films 6A and 7A, the thickness transition regions 6X and 7X are located on a portion stacked with the membrane 5Y of the piezoelectric layer 5, the membrane 5Y is likely to be damaged. As in the second and third modified examples, therefore, it is desirable that the thickness transition region 6X be located within a region where a multilayer section 9B contacts the insulating layer 4 and that the thickness transition region 7X be located within a region where a multilayer section 9C contacts the insulating layer 4. This makes it unlikely to damage the membrane 5Y.

The circuit configuration of the filter device 10 is not limited to that described above. As discussed above, the filter device 10 may be configured differently if it includes a ladder circuit section. In the first example embodiment, the acoustic wave resonator 1 is a parallel arm resonator located most closely to the first signal terminal 13 among the parallel arm resonators. However, the acoustic wave resonator 1 may be arranged at a different position.

As shown in FIG. 2, a recessed portion is provided in the insulating layer 4. The second dielectric film 7 and the piezoelectric layer 5 are disposed on the insulating layer 4 to cover this recessed portion. This provides a hollow portion, which serves as the cavity 2a. In the first example embodiment, the support 2 and the piezoelectric layer 5 are disposed so that a portion of the support 2 and part of the piezoelectric layer 5 oppose each other by sandwiching the cavity 2a therebetween. The recessed portion in the support 2 may be provided along the entirety of the insulating layer 4 and the support substrate 3. Alternatively, the recessed portion may be provided only in the support substrate 3 and be covered by the insulating layer 4. The recessed portion may be provided in another element, such as the piezoelectric layer 5. The cavity 2a may be a through-hole provided in the support 2.

The cavity 2a serves as an acoustic reflector in an example embodiment of the present invention. It is sufficient that at least a portion of the IDT electrode 8 overlap the acoustic reflector in a plan view. More specifically, it is sufficient that at least some of the electrode fingers of the IDT electrode 8 overlap the acoustic reflector in a plan view. The acoustic reflector can trap acoustic wave energy in the piezoelectric layer 5. As the acoustic reflector, an acoustic reflection film, which will be discussed later, may be provided. If the cavity 2a serves as the acoustic reflector, however, it can trap acoustic wave energy in the piezoelectric layer 5 more effectively.

It is preferable that multiple excitation regions C overlap the acoustic reflector in a plan view. With this arrangement, the acoustic reflector can trap acoustic wave energy in the piezoelectric layer 5 even more effectively.

In the first example embodiment, the piezoelectric layer 5 is made of lithium niobate. However, the material for the piezoelectric layer 5 is not limited to this. For example, lithium tantalate, such as LiTaO₃, aluminum nitride, such as AlN, scandium aluminum nitride, such as ScAlN, or PZT (lead zirconate titanate) may be used.

It is preferable, however, that the piezoelectric layer 5 be made of lithium niobate. Lithium niobate is a single crystal and has low viscosity loss so as to reduce energy loss of the principal mode. Additionally, lithium niobate has high piezoelectricity, which contributes to widening the passband of the filter device 10.

It is more preferable that lithium niobate having a Z-cut, an approximately 80°-160° rotated Y-cut with X-propagation, or an approximately 70°-100° rotated Y-cut with X-90° propagation be used as the material for the piezoelectric layer 5, for example. The use of this type of lithium niobate can increase the electromechanical coupling coefficient of the fundamental mode. When the piezoelectric layer 5 is made of Z-cut lithium niobate, the electromechanical coupling coefficient of the fundamental mode can be increased regardless of the propagation direction. The propagation direction is a direction parallel to the first main surface 5a of the piezoelectric layer 5 and also parallel to the electrode-finger perpendicular direction. In the specification, if cut angles are about 80°-160°, for example, it means that a range of the cut angles is from about 80° to about 160°, for example.

In the first example embodiment, the first and second dielectric films 6 and 7 are made of silicon oxide. However, the material for the first and second dielectric films 6 and 7 is not limited to silicon oxide. For example, silicon nitride, aluminum oxide, silicon oxynitride, or silicon oxycarbide, such as SiOC, may be used. It is preferable, however, that the first and second dielectric films 6 and 7 be made of silicon oxide. The use of silicon oxide can decrease the absolute value of the temperature coefficient of frequency (TCF) and thus enhance the frequency-temperature characteristics of the acoustic wave resonator 1. Additionally, the processability of the acoustic wave resonator 1 can be enhanced.

The material for the first dielectric film 6 and that of the second dielectric film 7 may be different from each other. The first and second dielectric films 6 and 7 are not limited to a single-layer dielectric film. At least one of the first and second dielectric films 6 and 7 may be a multilayer film. In the first example embodiment, the thickness of the first dielectric film 6 and that of the second dielectric film 7 are the same, but they may be different. The thicknesses of the first and second dielectric films 6 and 7 are suitably selected based on certain conditions, such as the filter characteristics, reliability, manufacturability.

The insulating layer 4 and the second dielectric film 7 shown in FIG. 2 may be integrally formed by the same material. In this case, too, the thickness Td_b of the second dielectric film 7 is the thickness of the second dielectric film 7 that overlaps the overlapping region A in a plan view. Alternatively, the insulating layer 4 and the second dielectric film 7 may be formed separately by different materials.

In the first example embodiment, between the first and second main surfaces 5a and 5b of the piezoelectric layer 5, the second main surface 5b is the surface facing the support 2. Nevertheless, the first main surface 5a may face the support 2. In this case, the first dielectric film 6 is disposed on the insulating layer 4. The insulating layer 4 and the first dielectric film 6 may be integrally formed by the same material. In this case, too, the thickness Td_f of the first dielectric film 6 is the thickness of the first dielectric film 6 that overlaps the overlapping region A in a plan view. Alternatively, the insulating layer 4 and the first dielectric film 6 may be formed separately by different materials.

As illustrated in FIG. 4, in the first example embodiment, the thickness Td_f of the first dielectric film 6 is thinner than the thickness of each electrode finger of the IDT electrode 8. Accordingly, the surface of the first dielectric film 6 becomes uneven. More specifically, the distance from the surface of the first dielectric film 6 that covers the electrode finger to the first main surface 5a of the piezoelectric layer 5 is different from the distance from the surface of the dielectric film 6 positioned between electrode fingers to the first main surface 5a of the piezoelectric layer 5. However, the thickness of the first dielectric film 6 is not limited to that described above.

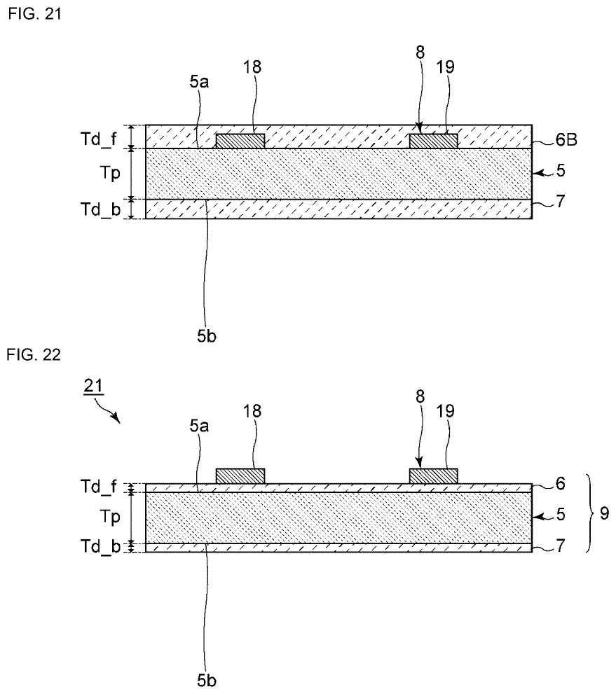

For example, in a fourth modified example of the first example embodiment illustrated in FIG. 21, the thickness of a first dielectric film 6B is thicker than the thickness of each electrode finger of the IDT electrode 8. The first dielectric film 6B covers the IDT electrode 8. The surface of the first dielectric film 6B is flat. In this case, too, the fractional bandwidth is about 8.5% or higher and about 0.322<(Td_f/Tp)+(Td_b/Tp)<about 0.786 and |(Td_f/Tp)−(Td_b/Tp)|<about 0.196, for example. With this configuration, as well as in the first example embodiment, a wide bandwidth of the filter device can be implemented, and also, the second- and third-order modes in the acoustic wave resonator can be suppressed in the acoustic wave resonator.

Examples in which the multilayer configuration or the electrode configuration of the acoustic wave resonator is different from the first example embodiment will be discussed below through illustration of second through fifth example embodiments. In the second through fifth example embodiments, as well as in the first example embodiment, the fractional bandwidth is about 8.5% or higher and about 0.322<(Td_f/Tp)+(Td_b/Tp)<about 0.786 and |(Td_f/Tp)−(Td_b/Tp)|<about 0.196, for example. With this configuration, in the second through fifth example embodiments, too, a wide bandwidth can be implemented, and also, the second- and third-order modes in the acoustic wave resonator can be suppressed.

FIG. 22 is a schematic elevational cross-sectional view of a pair of electrode fingers and its surrounding portion in an acoustic wave resonator in the second example embodiment.

The second example embodiment is different from the first example embodiment in that the first dielectric film 6 in an acoustic wave resonator 21 is disposed between the first main surface 5a of the piezoelectric layer 5 and the IDT electrode 8. Other than this point, the filter device of the second example embodiment is configured similarly to the filter device 10 of the first example embodiment.

The configuration of the acoustic wave resonator 21 in which the first dielectric film 6 is disposed between the piezoelectric layer 5 and the IDT electrode 8 may also be used for the configurations of example embodiments of the present invention other than the second example embodiment.

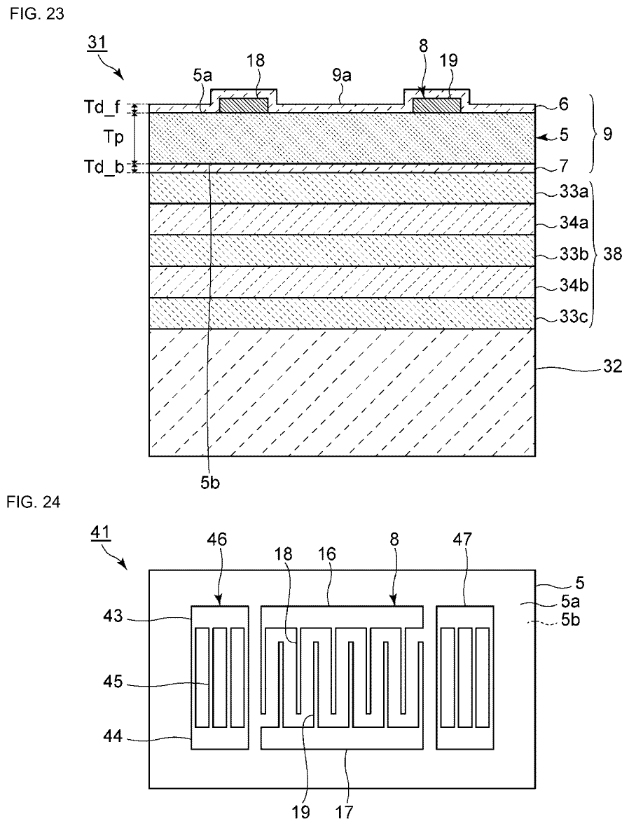

FIG. 23 is a schematic elevational cross-sectional view of a pair of electrode fingers and its surrounding portion in an acoustic wave resonator in a third example embodiment.

The third example embodiment is different from the first example embodiment in that the acoustic reflector in an acoustic wave resonator 31 is an acoustic reflection film 38 and also in that a support 32 is constituted only by a support substrate. Other than these points, the filter device of the third example embodiment is configured similarly to the filter device 10 of the first example embodiment.

The acoustic reflection film 38 is disposed on the surface of the support 32. The second dielectric film 7 is disposed on the acoustic reflection film 38. Accordingly, the piezoelectric layer 5 is indirectly disposed on the acoustic reflection film 38 with the second dielectric film 7 interposed therebetween. The acoustic wave reflector 31 may be configured differently if the support 32 and the piezoelectric layer 5 are disposed so that at least a portion of the support 32 and at least a portion of the piezoelectric layer 5 oppose each other by sandwiching the acoustic reflection film 38 therebetween.

The acoustic reflection film 38 is a multilayer body of multiple acoustic impedance layers. Specifically, the acoustic reflection film 38 includes multiple low acoustic impedance layers and multiple high acoustic impedance layers. The low acoustic impedance layers have a relatively low acoustic impedance. More specifically, the low acoustic impedance layers of the acoustic reflection film 38 are low acoustic impedance layers 33a, 33b, and 33c.

The high acoustic impedance layers have a relatively high acoustic impedance. More specifically, the high acoustic impedance layers of the acoustic reflection film 38 are high acoustic impedance layers 34a and 34b. The low acoustic impedance layers and the high acoustic impedance layers are alternately stacked on each other. The low acoustic impedance layer 33a is located most closely to the piezoelectric layer 5 among the acoustic impedance layers of the acoustic reflection film 38. The second dielectric film 7 is directly disposed on the low acoustic impedance layer 33a.

The acoustic reflection film 38 includes three low acoustic impedance layers and two high acoustic impedance layers. It is sufficient, however, that the acoustic reflection film 38 include at least one low acoustic impedance layer and at least one high acoustic impedance layer.

As the material for the low acoustic impedance layer, silicon oxide or aluminum, for example, may be used. As the material for the high acoustic impedance layer, a metal, such as platinum or tungsten, or a dielectric material, such as aluminum nitride, silicon nitride, or hafnium oxide, may be used.

For example, the second dielectric film 7 may serve as a low acoustic impedance layer. In this case, too, about 0.322<(Td_f/Tp)+(Td_b/Tp)<about 0.786 and |(Td_f/Tp)−(Td_b/Tp)|<about 0.196, for example.

When an acoustic wave is excited in the acoustic wave resonator 31, heat is generated in the excitation regions C. In the third example embodiment, the portions of the piezoelectric layer 5 corresponding to the excitation regions C are supported by the acoustic reflection film 38. This can enhance the heat dissipation characteristics of the acoustic wave resonator 31. Even when high power is applied to the acoustic wave resonator 31, the acoustic wave resonator 31 is unlikely to be damaged, thus improving electric power handling capability of the acoustic wave resonator 31 and the filter device. Additionally, since the piezoelectric layer 5 is supported by the acoustic reflection film 38, it is unlikely to be damaged by a thermal stress or a mechanical impact.

The configuration of the acoustic wave resonator 31 in which the acoustic reflection film 38 is used as the acoustic reflector may also be used for the configurations of example embodiments of the present invention other than the third example embodiment.

FIG. 24 is a schematic plan view of an acoustic wave resonator in a fourth example embodiment.

The fourth example embodiment is different from the first example embodiment in that an acoustic wave resonator 41 includes a pair of reflectors 46 and 47 and also in that the acoustic wave resonator 41 is configured to utilize a Lamb wave. Other than these points, the filter device of the fourth example embodiment is configured similarly to the filter device 10 of the first example embodiment.

The reflectors 46 and 47 are disposed on the first main surface 5a of the piezoelectric layer 5. Specifically, the reflectors 46 and 47 oppose each other by sandwiching the IDT electrode 8 therebetween in the electrode-finger perpendicular direction. If the IDT electrode 8 is disposed on the first dielectric film 6, the reflectors are also disposed on the first dielectric film 6.

The reflector 46 includes a pair of reflector busbars and multiple reflector electrode fingers 45. Specifically, the pair of reflector busbars are a first reflector busbar 43 and a second reflector busbar 44. The first and second reflector busbars 43 and 44 oppose each other. One end of each of the reflector electrode fingers 45 is connected to the first reflector busbar 43. The other ends of the reflector electrode fingers 45 are connected to the second reflector busbar 44. The reflector 47 is configured similarly to the reflector 46.

If the acoustic wave resonator 41 is configured to use a Lamb wave, it preferably includes a pair of reflectors. As a result, the resonance characteristics of the acoustic wave resonator 41 can be enhanced.

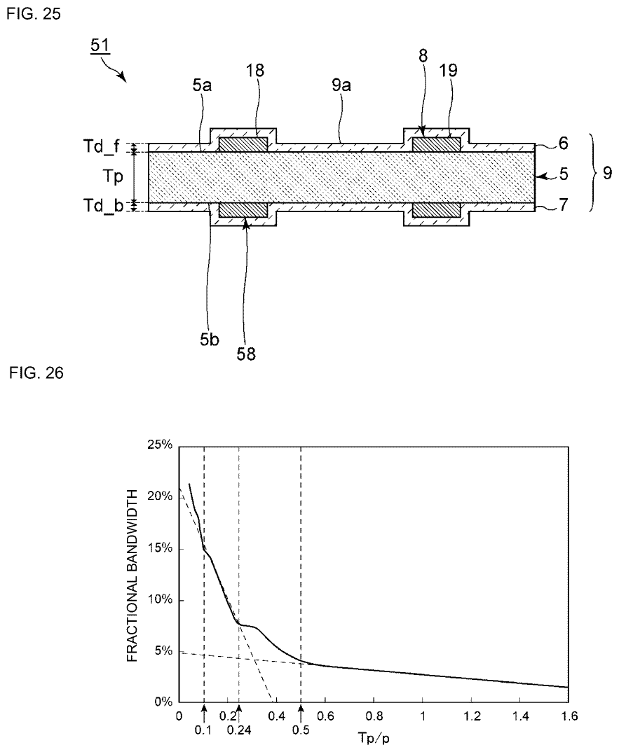

FIG. 25 is a schematic plan view of a pair of electrode fingers and its surrounding portion in an acoustic wave resonator in a fifth example embodiment.

The fifth example embodiment is different from the first example embodiment in that, in an acoustic wave resonator 51, an IDT electrode is provided on each of the first and second main surfaces 5a and 5b of the piezoelectric layer 5. Other than this point, the filter device of the fifth example embodiment is configured similarly to the filter device 10 of the first example embodiment.

Similarly to the first example embodiment, the IDT electrode 8 is disposed on the first main surface 5a of the piezoelectric layer 5. An IDT electrode 58 is disposed on the second main surface 5b. The IDT electrode 58 is configured similarly to the IDT electrode 8. That is, the IDT electrode 58 includes a pair of busbars and multiple electrode fingers. In the fifth example embodiment, the overlapping region defined based on the IDT electrode 8 and that based on the IDT electrode 58 overlap each other in a plan view.

In the fifth example embodiment, the thickness Td_b of the second dielectric film 7 is the thickness of the second dielectric film 7 positioned between electrode fingers.

The acoustic wave resonator 51 utilizes the thickness shear mode as the principal mode. However, the acoustic wave resonator 51 may be configured to utilize a Lamb wave. In this case, a pair of reflectors are preferably provided on each of the first and second main surfaces 5a and 5b of the piezoelectric layer 5. More specifically, it is preferable that a pair of reflectors be disposed on the first main surface 5a so as to oppose each other by sandwiching the IDT electrode 8 therebetween in the electrode-finger perpendicular direction. It is also preferable that a pair of reflectors be disposed on the second main surface 5b so as to oppose each other by sandwiching the IDT electrode 58 therebetween in the electrode-finger perpendicular direction.

A desirable configuration in an example embodiment of the present invention will be described below.

When a bulk wave of the thickness shear mode is utilized as the principal mode, it is preferable that Tp/p about 0.5, and more preferably, Tp/p about 0.24, for example. With this configuration, a bulk wave of the thickness shear mode can be suitably excited and the fractional bandwidth of the acoustic wave resonator can be sufficiently increased. The fractional bandwidth in this context is not the fractional bandwidth of the filter device, but the fractional bandwidth of one acoustic wave resonator. The fractional bandwidth is represented by (|Fa−Fr|/Fr)×100[%].

FIG. 26 is a graph illustrating the relationship between Tp/p and the fractional bandwidth of the acoustic wave resonator.

As is seen from FIG. 26, when Tp/p>about 0.5, the fractional bandwidth is less than about 5%, for example. In contrast, when Tp/p about 0.5, the fractional bandwidth can be improved to about 5% or higher, for example. Hence, the electromechanical coupling coefficient of a bulk wave of the thickness shear mode can be increased. When Tp/p about 0.24, the fractional bandwidth can be improved to about 7% or higher, for example. Hence, the electromechanical coupling coefficient of a bulk wave of the thickness shear mode can be effectively increased. In an example embodiment of the present invention, while the electromechanical coupling coefficient of the fundamental thickness shear mode can be increased, the second- and third-order modes can be suppressed.

It is preferable to satisfy that MR≤about 1.75(Tp/p)+0.075, for example, where MR is the metallization ratio of the electrode fingers to the excitation regions C. In this case, the fractional bandwidth of the acoustic wave resonator does not become excessively high, and the occurrence of spurious emission between the resonant frequency and the anti-resonant frequency can be prevented. Details of this will be explained below.

In the specification, the metallization ratio MR of the electrode fingers to the excitation regions C is the ratio of the piezoelectric layer 5 covered by a metal forming the electrode fingers to the excitation regions C in a plan view. More specifically, the ratio of the area of the first and second electrode fingers 18 and 19 within the excitation regions C to the area of the excitation regions C in a plan view is the metallization ratio MR. If the widths of the electrode fingers within the excitation regions C are uniform, the metallization ratio MR may be calculated by dividing the total width of the electrode fingers within the excitation regions C by the dimension of the excitation regions C in the electrode-finger perpendicular direction.

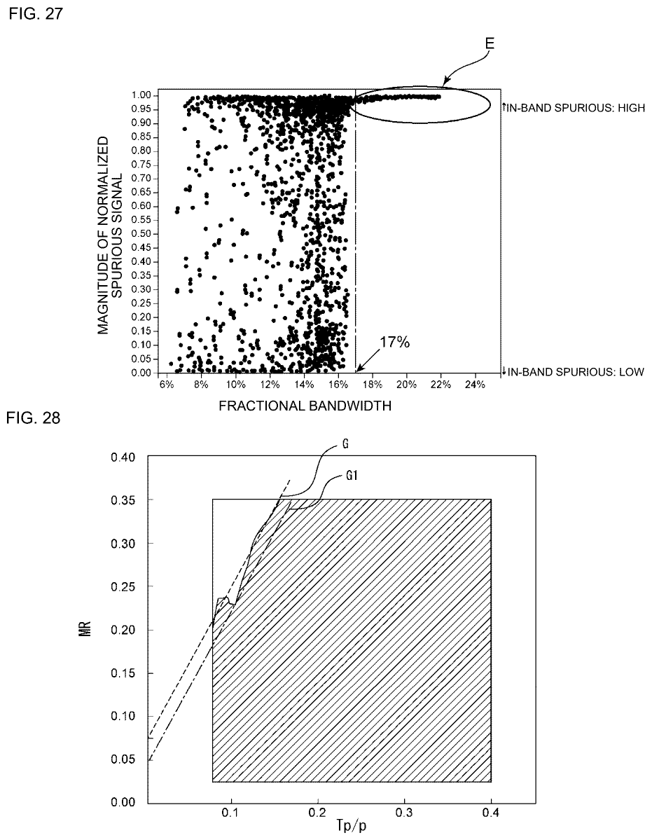

FIG. 27 is a graph illustrating the relationship between the fractional bandwidth of the acoustic wave resonator and the magnitude of a normalized spurious signal. The amount of phase shift of a spurious signal was measured every time the fractional bandwidth was adjusted by changing the thickness of the piezoelectric layer and/or the dimensions of electrode fingers. The measurement results of the amount of phase shift are shown in FIG. 27. Specifically, the magnitude of the normalized spurious signal in FIG. 27 represents the value obtained by normalizing the amount of phase shift of the impedance of the spurious signal by 180°. The results shown in FIG. 27 are obtained when a piezoelectric layer made of Z-cut LiNbO₃ was used. However, similar results are also likely to be obtained when a piezoelectric layer having another cut-angles is used.

The magnitude of the normalized spurious signal between the resonant frequency and the anti-resonant frequency becomes about 1.0, for example, in the region defined by the elliptical portion E in FIG. 27. When the fractional bandwidth of the acoustic wave resonator exceeds about 17%, the magnitude of the normalized spurious signal is likely to be about 1.0 or greater, for example. Accordingly, the fractional bandwidth is preferably about 17% or lower, for example. As a result, a spurious signal between the resonant frequency and the anti-resonant frequency can be suppressed.

FIG. 28 is a graph illustrating the relationships between Tp/p, the metallization ratio MR, and the fractional bandwidth. The fractional bandwidth was calculated every time Tp/p and the metallization ratio MR were changed. The calculation results of the fractional bandwidth are shown in FIG. 28.

The hatched portion in FIG. 28 is a region where the fractional bandwidth is about 17% or lower, for example. The boundary between the hatched portion and a portion without is substantially represented by the broken line G. The broken line G is expressed by MR=about 1.75(Tp/p)+0.075, for example. It is more preferable that MR≤about 1.75(Tp/p)+0.075, for example. In this case, the fractional bandwidth is likely to become about 17% or lower, for example.

The slope of the long dashed dotted line G1 in FIG. 28, which represents the metallization ratio MR with respect to Tp/p, is the same as the slope of the broken line G. The hatched portion on the right side of the long dashed dotted line G1 represents a region where the fractional bandwidth totally becomes about 17% or lower, for example. The long dashed dotted line G1 is expressed by MR=about 1.75 (Tp/p)+0.05, for example. It is more preferable that MR≤about 1.75(Tp/p)+0.05, for example. In this case, the fractional bandwidth is more likely to become about 17% or lower, for example.

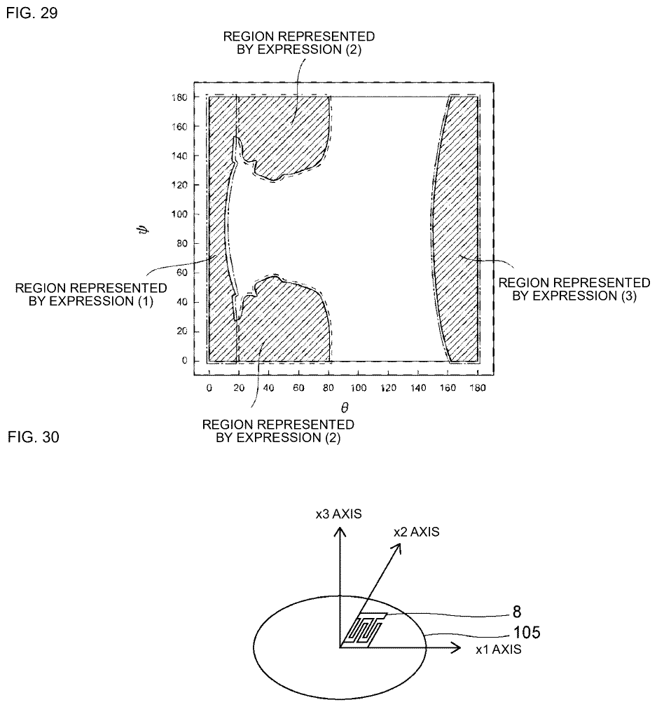

FIG. 29 is a graph illustrating a map of the fractional bandwidth with respect to the Euler angles (0°, θ, ψ) of LiNbO₃ in a case in which Tp/p is made to approach almost 0. The hatched portions in FIG. 29 are regions where a fractional bandwidth of at least about 5% or higher is obtained, for example. The ranges of the regions can approximate to the ranges represented by the following expressions (1), (2), and (3).

$$( 0 ° \pm 10 ° , 0 ° to 20 ° , a desirable angle of ψ ) \qquad Expression ( 1 )$$

$$( 0 ° \pm 10 ° , 20 ° to 80 ° , 0 ° to 60 ° {( 1 - {( θ - 50 )}^{2} / 900 )}^{1 / 2} ) or \qquad Expression ( 2 )$$

$$( 0 ° \pm 10 ° , 20 ° to 80 ° , [ 180 ° - 60 ° {( 1 - {( θ - 50 )}^{2} / 900 )}^{1 / 2} ] to 180 ° )$$

$$Expression ( 3 )$$

$$( 0 ° \pm 10 ° , [ 180 ° - 30 ° {( 1 - {( ψ - 90 )}^{2} / 8100 )}^{1 / 2} ] to 180 ° , a desirable angle of ψ )$$

The Euler angles (φ, θ, ψ) of lithium niobate of the piezoelectric layer are preferably in the range represented by the above-described expression (1), (2), or (3). Then, the fractional bandwidth of the acoustic wave resonator can be sufficiently wide. Similar advantages can be obtained when lithium tantalate is used for the piezoelectric layer.

The Euler angles of a piezoelectric crystal of the piezoelectric layer influence material constants, such as the piezoelectric constant, the elastic modulus, and the dielectric constant, of the piezoelectric crystal. When the Euler angles are within one of the above-described ranges, the fractional bandwidth of the acoustic wave resonator becomes wide.

In the specification, when one of the Euler angles is represented by about 0° to about 20°, for example, the range of this Euler angle is from about 0° to about 20°.

Euler angles are one of the indices representing the in-plane orientations of a piezoelectric crystal used in an acoustic wave device, such as an acoustic wave resonator. The angles φ, θ, ψ in the Euler angles are rotation angles with respect to the crystal axes of a piezoelectric crystal. More specifically, for example, the Euler angles are the rotation angles required to transform the coordinate system of the crystal axes of a piezoelectric crystal into the coordinate system used when the piezoelectric crystal is in an acoustic wave device.

The Euler angles will be explained below in greater details. In this explanation, four right-handed coordinate systems are used. A right-handed coordinate system is a three-axis orthogonal coordinate system in which the three axes are assigned in this order to the thumb, index finger, and middle finger of the right hand. For example, when the three axes are represented by (α, β, γ), the α axis is assigned to the thumb, the β axis is assigned to the index finger, and the γ axis is assigned to the middle finger.

When the Euler angles are represented by ((φ, θ, ψ), the coordinate system (α, β, γ) is transformed into the coordinate system (φ, θ, ψ) by the following three rotation operations 1), 2), and 3). 1) (α, β, γ) is rotated about the γ axis by φ, resulting in (α1, β1, γ1). Then, 2) (α1, β1, γ1) is rotated about the α1 axis by θ, resulting in (α2, β2, γ2). Then, 3) (α2, β2, γ2) is rotated about the γ2 axis by ψ, resulting in (α3, β3, γ3). It is assumed that the right-hand screw direction is the positive rotation direction.

By the above-described rotation operations 1), 2), and 3), (α, β, γ) is transformed into (α3, β3, γ3). The coordinate systems (α, β, γ) and (α3, β3, γ3) share the same origin. The Euler angles and the coordinate transformation method are also described in “Danseiha Soshi Gijutsu Handbook [Acoustic Wave Device Technology Handbook]p. 549”.

In the following example, unless otherwise stated, under the conditions that the acoustic wave resonator 1 is arranged in the filter device 10 as shown in FIG. 1 and the piezoelectric layer 5 is arranged as shown in FIG. 3, the material and the Euler angles of the piezoelectric layer 5 are varied.

To manufacture an acoustic wave device, such as the acoustic wave resonator 1, a wafer made of a piezoelectric crystal is divided, for example, thus obtaining multiple piezoelectric layers 5. For example, in a configuration in which an IDT electrode 8 is disposed on the main surface of the piezoelectric layer 5 or a wafer, a coordinate system including an axis extending in a direction normal to the main surface and an axis extending in the electrode-finger perpendicular direction is defined. The Euler angles serve as an index that represents the relationship between the crystal axes of the wafer or the piezoelectric layer 5 and the above-described coordinate system.

To put it more specifically, when the crystal axes of the wafer or the piezoelectric layer 5 are denoted by (X, Y, Z) and the coordinate system of the wafer or the piezoelectric layer 5 is denoted by (x1, x2, x3), (X, Y, Z) is transformed into (x1, x2, x3) by using the Euler angles (φ, θ, ψ).

FIG. 30 is a schematic diagram of the coordinate system obtained by transforming the crystal axes of a piezoelectric crystal using the Euler angles.

In FIG. 30, a wafer 105 and an IDT electrode 8 disposed on the wafer 105 are schematically shown. In the coordinate system of the wafer 105, the extending direction of the x1 axis is parallel to the electrode-finger perpendicular direction, the extending direction of the x3 axis is the direction normal to the main surface of the wafer 105, and the extending direction of the x2 axis is perpendicular to both of the x1 axis and the x3 axis. The coordinate system of the piezoelectric layer 5 obtained by dividing the wafer 105, such as that shown in FIG. 3, is also similar to that of the wafer 105. More specifically, the x3 axis extends in the direction normal to the first main surface 5a of the piezoelectric layer 5, and the x1 axis extends in parallel to the electrode-finger perpendicular direction.

The piezoelectric layer 5 has a positive (+) surface and a negative (−) surface with respect to the polarization direction. In this specification, a main surface of the piezoelectric layer 5 is defined as the positive surface if approximately 95% or more of the area of this surface faces the positive polarization direction, while a main surface of the piezoelectric layer 5 is defined as the negative surface if approximately 95% or more of the area of this surface faces the negative polarization direction. Additionally, in the specification, the direction from the negative (−) direction to the positive (+) direction of polarization is defined as the +Z direction. The +Z direction corresponds to the polarization direction of the piezoelectric crystal of the piezoelectric layer 5.

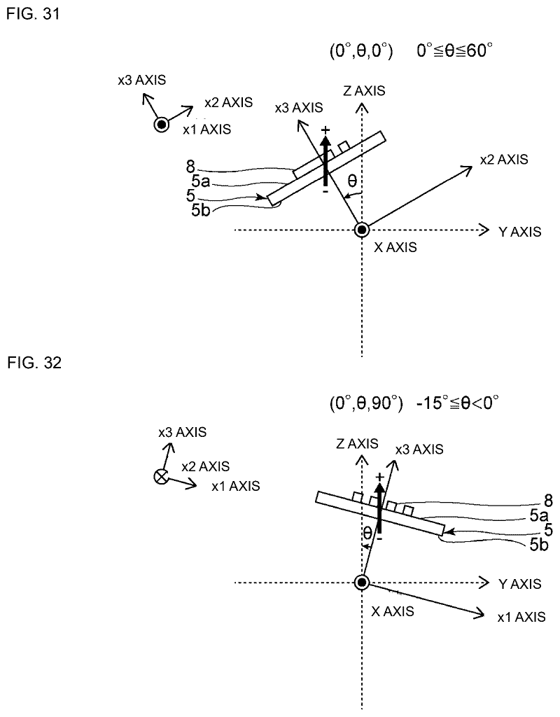

FIG. 31 is a schematic diagram illustrating the coordinate system of the piezoelectric layer when the angle θ in the Euler angles (0°, θ, 0°) of lithium niobate of the piezoelectric layer is about 0° to 60°.

The x3 axis extending in the direction normal to the main surface of the piezoelectric layer 5 is inclined from the Z axis of the piezoelectric layer 5 by an angle equal to the angle θ in the Euler angles (φ, θ, ψ). In the example in FIG. 31, the angle φ and the angle ψ in the Euler angles (φ, θ, ψ) are 0°. Accordingly, the x1 axis extending parallel to the electrode-finger perpendicular direction coincides with the X axis. The +Z direction, which is the polarization direction of the piezoelectric layer 5, is inclined from the x3 axis toward the x2 axis by the angle θ.

In this example, the first main surface 5a of the piezoelectric layer 5 is the positive surface, while the second main surface 5b of the piezoelectric layer 5 is the negative surface. The IDT electrode 8 is disposed on the positive surface of the piezoelectric layer 5.

U.S. Pat. No. 10,790,802 discloses that, when the angle β in the Euler angles (0°, β, 0°) of a piezoelectric substrate is about 0° to 60°, a bulk wave of the thickness shear mode is suitably excited and unwanted waves are suppressed. In U.S. Pat. No. 10,790,802, the piezoelectric substrate is made of lithium niobate. Based on this principle, when the angle θ in the Euler angles (0°, θ, 0°) of lithium niobate of the piezoelectric layer 5 is about 0° to 60°, a bulk wave of the thickness shear mode can be suitably excited.

Another example of the coordinate system of the piezoelectric layer that can suitably excite a bulk wave of the thickness shear mode is shown in FIG. 32.

FIG. 32 is a schematic diagram illustrating the coordinate system of the piezoelectric layer when the angle θ in the Euler angles (0°, θ, 90°) of lithium niobate of the piezoelectric layer is about −15° or greater and smaller than about 0°, for example.

In the example in FIG. 32, in the Euler angles ((φ, θ, ψ), the angle φ is about 0° and the angle ψ is about 90°, for example. Accordingly, the x1 axis extending in parallel to the electrode-finger perpendicular direction is inclined from the X axis by about 90°, for example. The x2 axis and the X axis extend in parallel to each other but in the opposite directions. The +Z direction, which is the polarization direction of the piezoelectric layer 5, is inclined from the x3 axis toward the opposite direction of the x1 axis by the angle equal to the absolute value of the angle θ. This is because the angle θ is a negative value. It can be said that the +Z direction is inclined from the x3 axis toward the x1 axis by θ+360°.

In this example, the first main surface 5a of the piezoelectric layer 5 is the positive surface, while the second main surface 5b of the piezoelectric layer 5 is the negative surface. The IDT electrode 8 is disposed on the positive surface of the piezoelectric layer 5.

U.S. Pat. No. 10,797,675 discloses that, when the angle β in the Euler angles (0°, β, 90°) of a piezoelectric substrate is −15° or greater and smaller than 0°, the electromechanical coupling coefficient of a bulk wave of the thickness shear mode is increased. In U.S. Pat. No. 10,797,675, the piezoelectric substrate is made of lithium niobate. Based on this principle, when the angle θ in the Euler angles (0°, θ, 90°) of lithium niobate of the piezoelectric layer 5 is, for example, about −15° or greater and smaller than about 0°, a bulk wave of the thickness shear mode can be suitably excited.

“Nihon Onkyo Gakkaishi [The Journal of the Acoustical Society of Japan] Vol. 36, No. 3 (1980) pp. 141-142” describes the characteristics of a surface acoustic wave in LiTaO₃, which is a trigonal (3m) crystal. It states that, based on the crystal symmetry, regarding the angle θ in the Euler angles (φ, θ, ψ), it is sufficient to examine the range of 0°≤θ≤180°. That is, when the angle θ of one trigonal (3m) crystal and that of the other trigonal (3m) crystal are different by 180°, the electrical characteristics of an acoustic wave device, such as an acoustic wave resonator, are bound to be substantially the same regardless of which one of the two crystals is used.

This is because changing the angle θ in the Euler angles (φ, θ, ψ) of a crystal by 180° is equivalent to changing the polarization direction of the crystal by 180°. When the angle θ of the crystal is changed by 180°, the only electrical characteristic that generally changes is the phase of an acoustic wave to be excited. Therefore, even when the angle θ of the crystal is changed by 180°, the electrical characteristics of an acoustic wave device, such as an acoustic wave resonator, remain substantially unchanged.

LiNbO₃, as well as LiTaO₃, is also a trigonal (3m) crystal, namely, a piezoelectric crystal belonging to the trigonal point group 3m. Accordingly, the above-described principle also applies to lithium niobate.

A description will be given of examples in which the ranges of the Euler angle θ of lithium niobate of the piezoelectric layer 5 are different from those shown in FIGS. 31 and 32 by 180°.

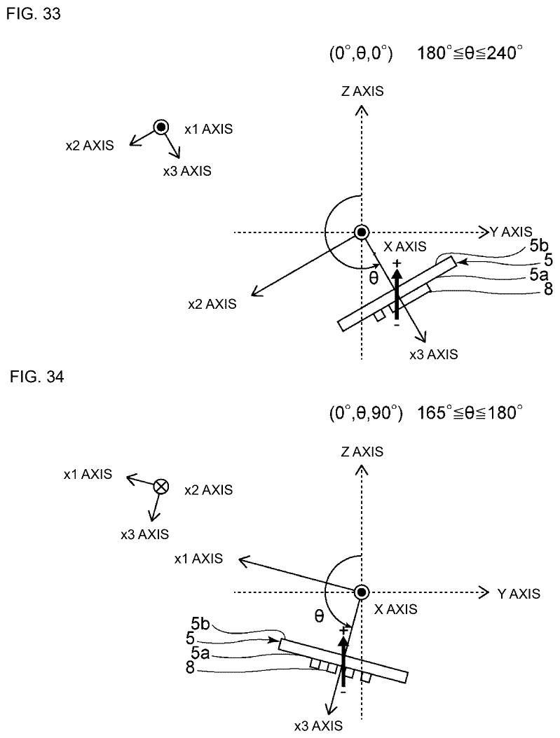

FIG. 33 is a schematic diagram illustrating the coordinate system of the piezoelectric layer when the angle θ in the Euler angles (0°, θ, 0°) of lithium niobate of the piezoelectric layer is about 180° to about 240°, for example. FIG. 34 is a schematic diagram illustrating the coordinate system of the piezoelectric layer when the angle θ in the Euler angles (0°, θ, 90°) of lithium niobate of the piezoelectric layer is about 165° to about 180°, for example.

Similarly to the example in FIG. 31, in the example in FIG. 33, the x1 axis extending parallel to the electrode-finger perpendicular direction coincides with the X axis. The +Z direction, which is the polarization direction of the piezoelectric layer 5, is inclined from the x3 axis toward the x2 axis by the angle θ. In this example, the first main surface 5a of the piezoelectric layer 5 is the negative surface, while the second main surface 5b of the piezoelectric layer 5 is the positive surface. The IDT electrode 8 is disposed on the negative surface of the piezoelectric layer 5.

Similarly to the example in FIG. 32, in the example in FIG. 34, the x2 axis and the X axis extend in parallel to each other but in the opposite directions. The +Z direction, which is the polarization direction of the piezoelectric layer 5, is inclined from the x3 axis toward the x1 axis by the angle θ. In this example, the first main surface 5a of the piezoelectric layer 5 is the negative surface, while the second main surface 5b of the piezoelectric layer 5 is the positive surface. The IDT electrode 8 is disposed on the negative surface of the piezoelectric layer 5.

The range of the Euler angle θ of lithium niobate of the piezoelectric layer 5 in the example in FIG. 33 is different from that in the example in FIG. 31 by 180°. The range of the Euler angle θ of lithium niobate of the piezoelectric layer 5 in the example in FIG. 34 is different from that in the example in FIG. 32 by 180°. In the examples in FIGS. 33 and 34, as well as in the examples in FIGS. 31 and 32, a bulk wave of the thickness shear mode can be suitably excited.

In the examples in FIGS. 31 and 32, the IDT electrode 8 is disposed on the positive surface of the piezoelectric layer 5. Conversely, in the examples in FIGS. 33 and 34, the IDT electrode 8 is disposed on the negative surface of the piezoelectric layer 5. The present inventor has discovered that, when the IDT electrode is disposed on the negative surface, polarization reversal is less likely to occur in the piezoelectric layer than when the IDT electrode is disposed on the positive surface. When polarization reversal occurs in the piezoelectric layer used in an acoustic wave resonator, the electrical characteristics of the acoustic wave resonator are degraded. This will be explained through illustration of a reference example.

The basic configuration of the reference example is similar to the configuration disclosed in U.S. Pat. No. 10,790,802. More specifically, a piezoelectric substrate is disposed on a support provided with a through-hole, and an IDT electrode is disposed on the piezoelectric substrate.

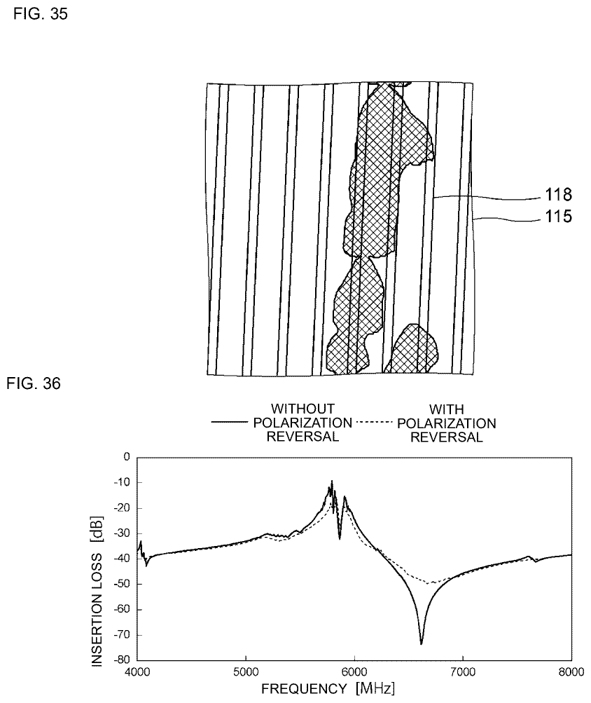

FIG. 35 illustrates a piezoresponse force microscopy image showing an example in which polarization reversal is occurring in the piezoelectric layer. FIG. 36 is a graph illustrating the admittance frequency characteristics of the acoustic wave resonator when polarization reversal is occurring in the piezoelectric layer and the admittance frequency characteristics when polarization reversal is not occurring in the piezoelectric layer. The piezoresponse force microscopy image shown in FIG. 35 is an image captured by an atomic force microscope (Dimension-FastScan (Icon) made by Bruker Japan K.K).

As shown in FIG. 35, an IDT electrode 118 is disposed on the positive surface of a piezoelectric layer 115. The cross-hatched portions in FIG. 35 indicate portions of the positive surface with the occurrence of polarization reversal. As is seen from FIG. 36, characteristic deterioration is observed both in the vicinity of the resonant frequency and in the vicinity of the anti-resonant frequency when polarization reversal occurs in the piezoelectric layer 115 compared with when polarization reversal does not occur.

As a result of comparing the examples in FIGS. 31 and 32 and those in FIGS. 33 and 34, it is seen that polarization reversal is less likely to occur in the piezoelectric layer 5 and the electrical characteristics of the acoustic wave resonator 1 are thus less likely to deteriorate in the examples in FIGS. 33 and 34. Additionally, the thickness shear mode can be suitably excited.

When a bulk wave of the thickness shear mode is suitably excited at the Euler angles (0°, θ, 0°), a bulk wave of this mode is also suitably excited when the Euler angle φ is in the range of about 0°±10°, for example. Likewise, a bulk wave of this mode is also suitably excited when the Euler angle ψ is in the range of about 0°±10°, for example.

Based on the above-described principle, it is preferable that the Euler angles ((φ, θ, ψ) of lithium niobate of the piezoelectric layer 5 be (about 0°±10°, about 1800 to 240°, about 0°±10°), for example. With this configuration, a bulk wave of the thickness shear mode can be suitably excited in the acoustic wave resonator 1. Additionally, polarization reversal is unlikely to occur in the piezoelectric layer 5, thus reducing the degradation of the electrical characteristics of the acoustic wave resonator 1. The filter characteristics of the filter device 10 including the acoustic wave resonator 1 are also less likely to deteriorate.

More preferably, the Euler angles ((φ, θ, ψ) of lithium niobate of the piezoelectric layer 5 are (about 0°, about 1800 to 240°, about 0°±3°), and even more preferably, (0°, 180° to 240°, 0°), for example. With this configuration, a bulk wave of the thickness shear mode is excited in the acoustic wave resonator 1 more suitably and more effectively. Additionally, polarization reversal is unlikely to occur in the piezoelectric layer 5, thus reducing the degradation of the electrical characteristics of the acoustic wave resonator 1. The filter characteristics of the filter device 10 including the acoustic wave resonator 1 are also less likely to deteriorate.

When a bulk wave of the thickness shear mode is suitably excited at the Euler angles (0°, θ, 90°), a bulk wave of this mode is also suitably excited when the Euler angle φ is in the range of about 0°±10°, for example. Likewise, a bulk wave of this mode is also suitably excited when the Euler angle ψ is in the range of about 90°±10°, for example.

It is preferable that the Euler angles ((φ, θ, ψ) of lithium niobate of the piezoelectric layer 5 be (about 0°±10°, about 165° to 180°, about 90°±10°), for example. With this configuration, a bulk wave of the thickness shear mode can be suitably excited in the acoustic wave resonator 1. Additionally, polarization reversal is unlikely to occur in the piezoelectric layer 5, thus reducing the degradation of the electrical characteristics of the acoustic wave resonator 1. The filter characteristics of the filter device 10 including the acoustic wave resonator 1 are also less likely to deteriorate.

More preferably, the Euler angles (φ, θ, ψ) of lithium niobate of the piezoelectric layer 5 are (about 0°, about 1650 to 180°, about 90°±3°), and even more preferably, (about 0°, about 165° to 180°, about 90°), for example. With this configuration, a bulk wave of the thickness shear mode can be excited in the acoustic wave resonator 1 more suitably and more effectively. Additionally, polarization reversal is unlikely to occur in the piezoelectric layer 5, thus reducing the degradation of the electrical characteristics of the acoustic wave resonator 1. The filter characteristics of the filter device 10 including the acoustic wave resonator 1 are also less likely to deteriorate.

It is not essential that the acoustic wave resonator 1 be configured to excite a bulk wave of the thickness shear mode. For example, the acoustic wave resonator 1 may be configured to excite a Lamb wave. When the acoustic wave resonator 1 utilizes an acoustic wave other than a bulk wave of the thickness shear mode, too, it is also preferable that the IDT electrode 8 be disposed on the negative surface of the piezoelectric layer 5. As a result, polarization reversal is unlikely to occur in the piezoelectric layer 5, thus reducing the degradation of the electrical characteristics of the acoustic wave resonator 1.

More specifically, it is preferable that the Euler angles (φ, θ, ψ) of a trigonal-point-group 3m piezoelectric crystal of the piezoelectric layer 5 be (about 0°±10°, θ, about 0°±10°) and about 90°<θ<about 270°, for example. In this case, the IDT electrode 8 is disposed on the negative surface of the piezoelectric layer 5. As a result, polarization reversal is unlikely to occur in the piezoelectric layer 5, thus reducing the degradation of the electrical characteristics of the acoustic wave resonator 1. The trigonal-point-group 3m piezoelectric crystal is lithium niobate or lithium tantalate.

More preferably, the Euler angles (φ, θ, ψ) of the trigonal-point-group 3m piezoelectric crystal of the piezoelectric layer 5 are (about 0°, θ, about 0°±3°) and about 90°<θ<about 270°, and even more preferably, (about 0°, θ, about 0°) and about 90°θ<0<about 270°, for example. As a result, polarization reversal is unlikely to occur in the piezoelectric layer 5, thus reducing the degradation of the electrical characteristics of the acoustic wave resonator 1.

In another example, it is preferable that the Euler angles (φ, θ, ψ) of the trigonal-point-group 3m piezoelectric crystal of the piezoelectric layer 5 be (about 0°±10°, θ, about 90°±10°) and about 90°<θ<about 270°, for example. In this case, too, the IDT electrode 8 is disposed on the negative surface of the piezoelectric layer 5. As a result, polarization reversal is unlikely to occur in the piezoelectric layer 5, thus reducing the degradation of the electrical characteristics of the acoustic wave resonator 1.

More preferably, the Euler angles (φ, θ, ψ) of the trigonal-point-group 3m piezoelectric crystal of the piezoelectric layer 5 are (about 0°, θ, about 90°±3°) and about 90°<θ<about 270°, and even more preferably, (about 0°, θ, about 90°) and about 90°θ<0<about 270°, for example. As a result, polarization reversal is unlikely to occur in the piezoelectric layer 5, thus reducing the degradation of the electrical characteristics of the acoustic wave resonator 1.

As discussed above, when the Euler angles (φ, θ, ψ) of lithium niobate or lithium tantalate of the piezoelectric layer 5 are in the range represented by the above-described expression (1), (2), or (3), the fractional bandwidth of the acoustic wave resonator can be sufficiently wide. Similar advantages can also be obtained when the range of the angle θ in expressions (1), (2), and (3) is different by 180°.

More specifically, it is preferable that the Euler angles ((φ, θ, ψ) of lithium niobate or lithium tantalate of the piezoelectric layer 5 be in the range represented by the following expression (4), (5), or (6). With this configuration, the fractional bandwidth of the acoustic wave resonator 1 can be sufficiently wide.

$$( 0 ° \pm 10 ° , 180 ° to 200 ° , a desirable angle of ψ ) \qquad Expression ( 4 )$$

$$( 0 ° \pm 10 ° , 200 ° to 260 ° , 0 ° to 60 ° {( 1 - {( θ - 50 )}^{2} / 900 )}^{1 / 2} ) or \qquad Expression ( 5 )$$

$$( 0 ° \pm 10 ° , 200 ° to 260 ° , [ 180 ° - 60 ° {( 1 - {( θ - 50 )}^{2} / 900 )}^{1 / 2} ] to 180 ° )$$

$$Expression ( 6 )$$

$$( 0 ° \pm 10 ° , [ 360 ° - 30 ° {( 1 - {( ψ - 90 )}^{2} / 8100 )}^{1 / 2} ] to 360 ° , a desirable angle of ψ )$$

When the Euler angles (φ, θ, ψ) of lithium niobate or lithium tantalate of the piezoelectric layer 5 are in the range represented by the above-described expression (4), (5), or (6), the IDT electrode 8 is disposed on the negative surface of the piezoelectric layer 5. With this configuration, polarization reversal is unlikely to occur in the piezoelectric layer 5, thus reducing the degradation of the electrical characteristics of the acoustic wave resonator 1. The filter characteristics of the filter device 10 including the acoustic wave resonator 1 are also less likely to deteriorate.

Specific approaches to identifying the passband of a filter device will be described below. If a data sheet is available for the filter device, the passband can be identified by referring to this data sheet. The passband indicated in the data sheet is the passband of the filter device. Examples of the passband are shown in Table 1 through Table 5. Table 1 and Table 2 show passbands for 4G, while Table 3 through Table 5 show passbands for 5G.

TABLE 1

| Band | Uplink (MHz) | Downlink (MHz) |
|---|---|---|
| 1 | 1920-1980 | 2110-2170 |
| 2 | 1850-1910 | 1930-1990 |
| 3 | 1710-1785 | 1805-1880 |
| 4 | 1710-1755 | 2110-2155 |
| 5 | 824-849 | 869-894 |
| 6 | 830-840 | 875-885 |
| 7 | 2500-2570 | 2620-2690 |
| 8 | 880-915 | 925-960 |
| 9 | 1749.9-1784.9 | 1844.9-1879.9 |
| 10 | 1710-1770 | 2110-2170 |
| 11 | 1427.9-1447.9 | 1475.9-1495.9 |
| 12 | 699-716 | 729-746 |
| 13 | 777-787 | 746-756 |
| 14 | 788-798 | 758-768 |
| 17 | 704-716 | 734-746 |
| 18 | 815-830 | 860-875 |
| 19 | 830-845 | 875-890 |
| 20 | 832-862 | 791-821 |

TABLE 2

| Band | Uplink (MHz) | Downlink (MHz) |
|---|---|---|
| 22 | 3410-3490 | 3510-3590 |
| 23 | 2000-2020 | 2180-2200 |
| 24 | 1626.5-1660.5 | 1525-1559 |
| 25 | 1850-1915 | 1930-1995 |
| 26 | 814-849 | 859-894 |
| 27 | 807-824 | 852-869 |
| 28 | 703-748 | 758-803 |
| 29 | — | 717-728 |
| 30 | 2305-2315 | 2350-2360 |
| 31 | 452.5-457.5 | 462.5-467.5 |
| 32 | — | 1452-1496 |

| | |
|---|---|
| 33 | 1900-1920 |
| 34 | 2010-2025 |
| 35 | 1850-1910 |
| 36 | 1930-1990 |
| 37 | 1910-1930 |
| 38 | 2570-2620 |
| 39 | 1880-1920 |
| 40 | 2300-2400 |
| 41 | 2496-2690 |
| 42 | 3400-3600 |
| 43 | 3600-3800 |
| 44 | 703-803 |
| 45 | 1447-1467 |
| 46 | 5150-5925 |
| 47 | 5855-5925 |
| 48 | 3550-3700 |

49

| | |
|---|---|
| 50 | 1432-1517 |
| 51 | 1427-1432 |
| 52 | 3300-3400 |

| | | |
|---|---|---|
| 65 | 1920-2010 | 2110-2200 |
| 66 | 1710-1780 | |
| 67 | — | 738-758 |
| 68 | 698-728 | 753-783 |
| 69 | — | 2570-2620 |
| 70 | 1695-1710 | 1995-2020 |
| 71 | 663-698 | 617-652 |
| 72 | 451-456 | 461-466 |
| 73 | 450-455 | 460-465 |
| 74 | 1427-1470 | 1475-1518 |
| 75 | — | 1432-1517 |
| 76 | | 1427-1432 |
| 85 | 698-716 | 728-746 |
| 252 | — | 5150-5250 |
| 255 | | 5725-5850 |

TABLE 3

| Band | Uplink [MHz] | Downlink [MHz] |
|---|---|---|
| n2 | 1850-1910 | 1930-1990 |
| n3 | 1710-1785 | 1805-1880 |
| n5 | 824-849 | 869-894 |
| n7 | 2500-2570 | 2620-2690 |
| n8 | 880-915 | 925-960 |
| n12 | 699-716 | 729-746 |
| n13 | 777-787 | 746-356 |
| n14 | 788-798 | 758-768 |
| n18 | 815-830 | 860-875 |
| n20 | 832-862 | 791-821 |
| n24 | 1626.5-1660.5 | 1525-1559 |
| n25 | 1850-1915 | 1930-1995 |
| n26 | 814-849 | 859-894 |
| n28 | 703-748 | 758-803 |
| n29 | — | 717-728 |
| n30 | 2305-2315 | 2350-2360 |

| | |
|---|---|
| n34 | 2010-2025 |
| n38 | 2570-2620 |
| n39 | 1880-1920 |
| n40 | 2300-2400 |
| n41 | 2496-2690 |
| n46 | 5150-5925 |
| n47 | 5855-5925 |
| n48 | 3550-3700 |
| n50 | 1432-1517 |
| n51 | 1427-1432 |
| n53 | 2483.5-2495 |

| | | |
|---|---|---|
| n65 | 1920-2010 | 2110-2200 |
| n66 | 1710-1780 | 2110-2200 |
| n67 | — | 738-758 |
| n70 | 1695-1710 | 1995-2020 |
| n71 | 663-698 | 617-652 |
| n74 | 1427-1470 | 1475-1518 |
| n75 | — | 1432-1517 |
| n76 | | 1427-1432 |

| | |
|---|---|
| n77 | 3300-4200 |
| n78 | 3300-3800 |
| n79 | 4400-5000 |

| | | |
|---|---|---|
| n80 | 1710-1785 | — |
| n81 | 880-915 | |
| n82 | 832-862 | |
| n83 | 703-748 | |
| n84 | 1920-1980 | |
| n85 | 698-716 | 728-746 |
| n86 | 1710-1780 | — |
| n89 | 824-849 | |

| | |
|---|---|
| n90 | 2496-2690 |

TABLE 4

| Band | Uplink [MHz] | Downlink [MHz] |
|---|---|---|
| n91 | 832-862 | 1427-1432 |
| n92 | 832-862 | 1432-1517 |
| n93 | 880-915 | 1427-1432 |
| n94 | 880-915 | 1432-1517 |
| n95 | 2010-2025 | — |
| n96 | 5925-7125 | |
| n97 | 2300-2400 | |
| n98 | 1880-1920 | |
| n99 | 1626.5-1660.5 | |
| n100 | 874.4-880 | 919.4-925 |
| n101 | 1900-1910 | — |
| n102 | 5925-6425 | |
| n104 | 6425-7125 | |

TABLE 5

| Band | Uplink/Downlink [GHz] |
|---|---|
| n257 | 26.50-29.50 |
| n258 | 24.25-27.50 |
| n259 | 39.50-43.50 |
| n260 | 37.00-40.00 |
| n261 | 27.50-28.35 |
| n262 | 47.20-48.20 |
| n263 | 57.00-71.00 |

If a data sheet is not available for the filter device, the passband characteristics of the filter device may be measured to determine the passband of the filter device. Specifically, a network analyzer, for example, may be used to measure the passband. An example of the network analyzer is “Keysight P5027B USB vector network analyzer made by Keysight Technologies, Inc.”.

A fixture may be used to connect the filter device to a network analyzer when measuring the passband characteristics. The fixture may include a pair of connectors and a substrate, for example. One connector is connected to the terminal of the filter device to be connected to the input potential, while the other connector is connected to the terminal of the filter device to be connected to the output potential. The substrate grounds the terminal of the filter device to be connected to the ground potential.

For example, the filter device is first placed on the substrate of the fixture. The terminal of the filter device to be connected to the ground potential is brought into contact with the substrate of the fixture, thus grounding this terminal.

One connector of the fixture is connected to the terminal of the filter device to be connected to the input potential, while the other connector is connected to the terminal of the filter device to be connected to the output potential. Typically, the characteristic impedance in the path from each connector of the fixture to the corresponding terminal of the filter device is designed to be 50Ω. With the use of a cable, for example, one connector is connected to the input port of the network analyzer, and the other connector is connected to the output port. The terminal of the filter device to be connected to the input potential can be electrically connected to the input port of the network analyzer, while the terminal of the filter device to be connected to the output potential can be electrically connected to the output port of the network analyzer.

The conditions for measuring the passband characteristics of the filter device are as follows.
Temperature: room temperature
Input power: 0 dBm
Passband characteristics to be measured: S21

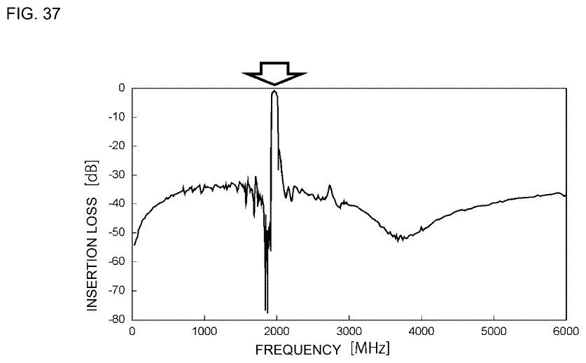

FIG. 37 is a graph illustrating an example of the passband characteristics of the filter device.

The passband characteristics are measured by changing the frequency. The passband of the filter device can be determined by comparing the band with small insertion loss, such as that indicated by the arrow in FIG. 37, with the passbands shown in Table 1 through Table 5. The passbands in Table 1 through Table 5 are only examples and the passbands to be compared with the measurement results are not limited to those in Table 1 through Table 5.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device having a passband, the filter device comprising:
a plurality of resonators including an acoustic wave resonator;
the acoustic wave resonator including:
a piezoelectric layer including first and second main surfaces opposing each other;
an IDT electrode directly or indirectly provided on the first main surface of the piezoelectric layer and including a plurality of electrode fingers;
a first dielectric film provided on the first main surface of the piezoelectric layer; and
a second dielectric film provided on the second main surface of the piezoelectric layer; wherein
a direction perpendicular to an extending direction of the plurality of electrode fingers is defined as an electrode-finger perpendicular direction, and as viewed in the electrode-finger perpendicular direction, a region where the electrode fingers adjacent to each other overlap each other is defined as an overlapping region;
the first and second dielectric films overlap the overlapping region in a plan view;
a fractional bandwidth is about 8.5% or higher, the fractional bandwidth being represented by ((FH−FL)/FC)×100[%], where FH is a highest frequency of the passband, FL is a lowest frequency of the passband, and FC is a center frequency of the passband; and
about 0.322<(Td_f/Tp)+(Td_b/Tp)<about 0.786 and |(Td_f/Tp)−(Td_b/Tp)|<about 0.196, where Tp is a thickness of the piezoelectric layer corresponding to the overlapping region, Td_f is a thickness of the first dielectric film that overlaps the overlapping region in a plan view, and Td_b is a thickness of the second dielectric film that overlaps the overlapping region in a plan view.

2. The filter device according to claim 1, wherein the acoustic wave resonator is configured to utilize a bulk wave of a thickness shear mode.

3. The filter device according to claim 1, further comprising:
a support directly or indirectly stacked on the piezoelectric layer; wherein
an acoustic reflector is provided in or on the support at a position at which the acoustic reflector overlaps the plurality of electrode fingers in a plan view; and
Tp/p is about 0.5 or smaller, where p is a center-to-center distance between the electrode fingers adjacent to each other.

4. The filter device according to claim 3, wherein Tp/p is about 0.24 or smaller.

5. The filter device according to claim 3, wherein
in the region where the electrode fingers adjacent to each other overlap each other in the electrode-finger perpendicular direction, a center-to-center region between adjacent electrode fingers is defined as an excitation region; and
MR≤about 1.75(Tp/p)+0.075 is satisfied, where MR is a metallization ratio of the electrode fingers to the excitation region.

6. The filter device according to claim 3, wherein
the acoustic reflector includes a cavity; and
the support and the piezoelectric layer are provided so that a portion of the support and a portion of the piezoelectric layer oppose each other by sandwiching the cavity therebetween.

7. The filter device according to claim 3, wherein
the acoustic reflector includes an acoustic reflection film including a high acoustic impedance layer having a relatively high acoustic impedance and a low acoustic impedance layer having a relatively low acoustic impedance; and
the support and the piezoelectric layer are provided so that at least a portion of the support and at least a portion of the piezoelectric layer oppose each other by sandwiching the acoustic reflection film therebetween.

8. The filter device according to claim 1, wherein the acoustic wave resonator is configured to utilize a Lamb wave.

9. The filter device according to claim 1, wherein:
the piezoelectric layer is made of lithium niobate or lithium tantalate; and
Euler angles (φ, θ, ψ) of lithium niobate or lithium tantalate of the piezoelectric layer are in a range represented by expression (1), (2), or (3); where
$$( 0 ° \pm 10 ° , 0 ° to 20 ° , a desirable angle of ψ ) \qquad Expression ( 1 )$$
$$( 0 ° \pm 10 ° , 20 ° to 80 ° , 0 ° to 60 ° {( 1 - {( θ - 50 )}^{2} / 900 )}^{1 / 2} ) or \qquad Expression ( 2 )$$
$$( 0 ° \pm 10 ° , 20 ° to 80 ° , [ 180 ° - 60 ° {( 1 - {( θ - 50 )}^{2} / 900 )}^{1 / 2} ] to 180 ° )$$
$$Expression ( 3 )$$
$$( 0 ° \pm 10 ° , [ 180 ° - 30 ° {( 1 - {( ψ - 90 )}^{2} / 8100 )}^{1 / 2} ] to 180 ° , a desirable angle of ψ ) .$$

10. the filter device according to claim 1, wherein
the piezoelectric layer is made of lithium nobiate or lithium tantalate; and
$$( 0 ° \pm 10 ° , 180 ° to 200 ° , a desirable angle of ψ ) \qquad Expression ( 4 )$$
$$( 0 ° \pm 10 ° , 200 ° to 260 ° , 0 ° to 60 ° {( 1 - {( θ - 50 )}^{2} / 900 )}^{1 / 2} ) or \qquad Expression ( 5 )$$
$$( 0 ° \pm 10 ° , 200 ° to 260 ° , [ 180 ° - 60 ° {( 1 - {( θ - 50 )}^{2} / 900 )}^{1 / 2} ] to 180 ° )$$
$$Expression ( 6 )$$
$$( 0 ° \pm 10 ° , [ 360 ° - 30 ° {( 1 - {( ψ - 90 )}^{2} / 8100 )}^{1 / 2} ] to 360 ° , a desirable angle of ψ ) .$$

11. The filter device according to claim 1, wherein the piezoelectric layer is made of lithium niobate.

12. The filter device according to claim 1, wherein the first and second dielectric films are made of silicon oxide.

13. The filter device according to claim 1, wherein the filter device is a ladder filter.

14. The filter device according to claim 1, wherein the filter device includes a plurality of series arm resonators and a plurality of parallel arm resonators.

15. The filter device according to claim 1, wherein the filter device is configured to operate in a 5G communication system.

16. The filter device according to claim 1, wherein the piezoelectric layer includes lithium niobate, lithium tantalate, aluminum nitride, scandium aluminum nitride, or PZT.

17. The filter device according to claim 1, wherein the first and second dielectric films are made of silicon oxide, silicon nitride, aluminum oxide, silicon oxynitride, or silicon oxycarbide.

18. The filter device according to claim 1, wherein the first dielectric film is between the first main surface and the IDT electrode.

19. The filter device according to claim 3, wherein the acoustic reflector includes an acoustic reflection film and the support includes only a support substrate.

20. The filter device according to claim 1, wherein the acoustic wave resonator includes a pair of reflectors and is configured to use a Lamb wave.
